(19) United States
(12) Patent Application Publication
(10) Pub. No.: US 2009/0145651 A1
(43) Pub. Date: Jun. 11, 2009

(54) MULTILAYER WIRING BOARD AND METHOD FOR PRODUCING THE SAME

(75) Inventors: Toyokazu YOSHINO, Fukuoka (JP); Shinji MORIMOTO, Fukuoka (JP); Kouji NAKASHIMA, Fukuoka (JP); Shigeki OGATA, Fukuoka (JP)

Correspondence Address: GREENBLUM & BERNSTEIN, P.L.C., 1950 ROLAND CLARKE PLACE, RESTON, VA, 20191, US

(73) Assignee: PANASONIC CORPORATION, Osaka (JP)

(21) Appl. No.: 12/331,754

(22) Filed: Dec. 10, 2008

(30) Foreign Application Priority Data
Dec. 11, 2007 (JP) 2007-319174
Dec. 11, 2007 (JP) 2007-319175

(51) Int. Cl. H05K 1/11; C25D 5/02

(52) U.S. Cl. 174/263; 205/114

(57) ABSTRACT

A multilayer wiring board 1 includes an insulating layer 2, a copper wiring upper layer 3 and a copper wiring lower layer 4 laminated on both surfaces of the insulating layer 2, a through hole 5 pierced through the insulating layer 2 and at least one of the copper wiring layers, and a solder conductor 6 which is filled in the through hole 5 and makes connection and electric continuity between the copper wiring upper layer 3 and the copper wiring lower layer 4, where solder exposed surfaces on which a part of the solder conductor 6 is in contact with the copper wiring upper layer 3 or the copper wiring lower layer 4 and exposed to the outermost surface, and the surfaces of the copper wiring upper layer 3 and the copper wiring lower layer 4 are coated and integrated by plating films 8, and the metal-made plating films 8 are made of a metal having an ionization tendency greater than that of the solder conductor 6.

### BACKGROUND

1. Field of the Invention

The present invention relates to a multilayer wiring board which is a wiring board on which various surface-mount electronic components are mounted, and has an especially high connection reliability, and a method for producing the same.

2. Description of the Related Art

In recent years, along with a reduction in size and weight of electronic devices, the wiring density of a wiring board to be used has also tended to increase. As a means for increasing the wiring density of the wiring board, there are limitations to realize this only by miniaturization of the copper wiring layers. Therefore, a multilayer wiring board which includes laminated copper wiring layers and has an interlayer connecting portion provided in the insulating layer between the copper wiring layers to three-dimensionally connect the copper wiring layers to further increase the wiring density, has gained attention.

Conventionally, the multilayer wiring board has features that differ depending on a difference of an insulating layer used. For example, when a glass cloth-impregnated epoxy resin base material (hereinafter, abbreviated to glass epoxy base material) which is the most common is used as the insulating layer, cost reduction can be realized, and when an electric insulating film such as polyimide is used, reduction in thickness and weight is possible. The multilayer wiring board has features that vary according to this difference in the insulating layer, however, as the interlayer connection method, basically the same technique is used. This interlayer connection method will be described below by using a multilayer wiring board using a polyimide film by way of example.

In this method, a through hole is made in a copper-clad double-sided board having copper foils laminated on both surfaces of an insulating layer made of a polyimide film, and on the through hole wall surface, a copper plating film is formed to three-dimensionally connect the copper foils on both surfaces of the insulating layer (for example, refer to Patent document 1).

This interlayer connection method is called as plating through hole method, and is the most common interlayer connection method. This production method includes two major steps of a step of applying conductive treatment to the insulating through hole wall surface by electroless plating, and a step of copper thick plating by electrolytic plating. As a feature, the copper plating film inside the through hole and the insulating layer made of a polyimide film have substantially the same thermal expansion coefficient, and therefore, excellent connection reliability against heat is obtained.

However, when copper thick plating is applied, not only the thickness of the copper plating film inside the through hole but also the thicknesses of the copper foils formed on both surfaces of the insulating layer are increased, and it becomes difficult to miniaturize the copper wiring layers by subsequent etching. In addition, the process becomes long, so that this method has a problem in productivity.

As an interlayer connection method for solving these problems, a method in which a solder paste is printed on the inside of the through hole and molten and solidified (for example, refer to Patent document 2), etc., have been proposed. As a feature of this method, a multilayer wiring board can be manufactured through processes easier than in the plating through hole method, so that the productivity is increased, and interlayer connection is made after the copper wiring layers are formed, so that the interlayer connection has no influence on the thicknesses of the copper foils in process, and does not hinder miniaturization of the copper wiring layers.

However, the thermal expansion coefficient of solder is higher than that of the insulating layer made of a polyimide film, so that when heating, solder inside the through hole expands more than the insulating layer, and the joining interface between the copper wiring layer on the insulating layer surface and the solder may separate. The method using solder has such a problem of insufficient thermal connection reliability.

The problems described above are common in a multilayer wiring board of a glass epoxy base material obtained according to the same interlayer connection method.

Patent document 1: JP-A-05-175636

Patent document 2: JP-A-07-176847

As described above, the interlayer connection of the multilayer wiring board according to the conventional plating through hole method has problems in miniaturization of the copper wiring layers and improvement in productivity although it has excellent connection reliability, and the method using solder has a problem in connection reliability although it realizes the above-described miniaturization of the copper wiring layers and improvement in productivity.

Therefore, concerning interlayer connection of a multilayer wiring board, a multilayer wiring board which realizes both high connection reliability and miniaturization of copper wiring layers and has high productivity has been demanded.

### SUMMARY

In view of the above-described problems, an object of the present invention is to provide a multilayer wiring board having an interlayer connecting portion which has high connection reliability and is optimum for miniaturization of the copper wiring layers, and has high productivity, and a method for producing the same.

To solve the above-described problems, a multilayer wiring board of the present invention includes an insulating layer; copper wiring layers laminated on both surfaces of the insulating layer; a through hole pierced through the insulating layer and at least one of the copper wiring layers; and a solder conductor which is filled in the through hole and makes connection and electric continuity between the copper wiring layers, wherein solder exposed surfaces on which a part of the solder conductor is in contact with the copper wiring layers and exposed to the outermost surfaces and the surfaces of the copper wiring layers are coated by metal plating films, the solder conductor and the wiring layers are joined by the metal plating films, and the metal plating films are made of a metal whose ionization tendency is greater than that of the solder conductor.

### BRIEF DESCRIPTION OF THE DRAWINGS

FIG. 1 is an essential portion sectional view of a multilayer wiring board in an embodiment of the present invention;

FIG. 2(a) is an essential portion sectional view of a double-sided copper-clad lamination board as a raw material in an embodiment of the present invention, FIG. 2(b) is an essential portion sectional view of the double-sided wiring board on which copper wiring layers are formed in an embodiment of the present invention; FIG. 2(c) is an essential portion sectional view of the double-sided wiring board in which a through hole is formed in an embodiment of the present invention, FIG. 2(d) is an essential portion sectional view of the double-sided wiring board before a copper-core solder ball is press-fitted in an embodiment of the present invention, FIG. 2(e) is an essential portion sectional view of the double-sided wiring board after a copper-core solder ball is press-fitted in a deformed manner in an embodiment of the present invention, FIG. 2(f) is an essential portion sectional view of the double-sided wiring board during formation of plating films in an embodiment of the present invention, and FIG. 2(g) is an essential portion sectional view of a multilayer wiring board after an interlayer connection is made in an embodiment of the present invention;

FIG. 3(a) is an essential portion sectional view of a one-sided copper-clad lamination board with a bonding layer as a raw material in an embodiment of the present invention, FIG. 3(b) is an essential portion sectional view of a one-sided wiring board with a bonding layer on which a copper wiring layer is formed in an embodiment of the present invention, FIG. 3(c) is an essential portion sectional view of the one-sided wiring board with a bonding layer in which a through hole is formed in an embodiment of the present invention, FIG. 3(d) is an essential portion sectional view of a multilayer wiring board in which a blind via hole is formed in an embodiment of the present invention, FIG. 3(e) is an essential portion sectional view of a double-sided wiring board after a copper-core solder ball is press-fitted in a deformed manner in an embodiment of the present invention, and FIG. 3(f) is an essential portion sectional view of the multilayer wiring board after an interlayer connection is made by forming a plating film in an embodiment of the present invention; and

FIG. 4(a) is an essential portion sectional view of a multilayer wiring board after being laminated in an embodiment of the present invention, and FIG. 4(b) is an essential portion sectional view of another multilayer wiring board after being laminated in an embodiment of the present invention;

FIG. 5 is a main portion sectional view of a multilayer wiring board in an embodiment of the present invention;

FIG. 6(a) is an essential portion sectional view of a double-sided copper-clad lamination board which is a raw material in an embodiment of the present invention, FIG. 6(b) is an essential portion sectional view of the double-sided wiring board in which a through hole is formed in an embodiment of the present invention, FIG. 6(c) is an essential portion sectional view of the double-sided wiring board before a copper-core solder ball is press-fitted in an embodiment of the present invention, FIG. 6(d) is an essential portion sectional view of the double-sided wiring board after the copper-core solder ball is press-fitted in a deformed manner in an embodiment of the present invention, FIG. 6(e) is an essential portion sectional view of the double-sided wiring board during formation of copper plating films in an embodiment of the present invention, and FIG. 6(f) is an essential portion sectional view of the multilayer wiring board after an interlayer connection is made in an embodiment of the present invention;

FIG. 7(a) is an essential portion sectional view of a double-sided copper-clad lamination board which is a raw material in an embodiment of the present invention, FIG. 7(b) is an essential portion sectional view of a double-sided wiring board on which copper wiring layers are formed in an embodiment of the present invention, FIG. 7(c) is an essential portion sectional view of the double-sided wiring board in which a through hole is formed in an embodiment of the present invention, FIG. 7(d) is an essential portion sectional view of the double-sided wiring board after the copper-core solder ball is press-fitted in a deformed manner in an embodiment of the present invention, and FIG. 7(e) is an essential portion sectional view of the multilayer wiring board after copper plating films are formed in an embodiment of the present invention;

FIG. 8(a) is an essential portion sectional view of a one-sided copper-clad lamination board with a bonding layer as a raw material in an embodiment of the present invention, FIG. 8(b) is an essential portion sectional view of a one-sided wiring board with a bonding layer on which a copper wiring layer is formed in an embodiment of the present invention, FIG. 8(c) is an essential portion sectional view of the one-sided wiring board with a bonding layer in which a through hole is formed in an embodiment of the present invention, FIG. 8 (d) is an essential portion sectional view of a multilayer wiring board in which a blind via hole is formed in an embodiment of the present invention, FIG. 8(e) is an essential portion sectional view of a double-sided wiring board after a copper-core solder ball is press-fitted in a deformed manner in an embodiment of the present invention, and FIG. 8(f) is an essential portion sectional view of a multilayer wiring board after an interlayer connection is made by forming a copper plating film in an embodiment of the present invention;

FIG. 9(a) is an essential portion sectional view of a multilayer wiring board after being laminated in an embodiment of the present invention, and FIG. 9(b) is an essential portion sectional view of another multilayer wiring board after being laminated in an embodiment of the present invention;

FIG. 10 is an essential portion sectional view of a multilayer wiring board of an embodiment of the present invention;

FIG. 11(a) is an essential portion sectional view of a double-sided copper-clad lamination board that is a raw material in an embodiment of the present invention,

FIG. 11(b) is an essential portion sectional view of a double-sided wiring board on which copper wiring layers are formed,

FIG. 11(c) is an essential portion sectional view of the double-sided wiring board in which a through hole is formed in an embodiment of the present invention,

FIG. 11(d) is an essential portion sectional view of the double-sided wiring board before a copper-core solder ball is press-fitted in an embodiment of the present invention,

FIG. 11(e) is an essential portion sectional view of the double-sided wiring board after the copper-core solder ball is press-fitted in a deformed manner in an embodiment of the present invention,

FIG. 11(f) is an essential portion sectional view of the double-sided wiring board during coating of a conductive nanoink in an embodiment of the present invention, and

FIG. 11(g) is an essential portion sectional view of the multilayer wiring board on which copper wiring layers between which an interlayer connection is made are formed in an embodiment of the present invention;

FIG. 12(a) is an essential portion sectional view of a one-sided copper-clad lamination board with a bonding layer as a raw material in an embodiment of the present invention,

FIG. 12(b) is an essential portion sectional view of a one-sided wiring board with a bonding layer on which a copper wiring layer is formed in an embodiment of the present invention,

FIG. 12(c) is an essential portion sectional view of the one-sided wiring board with a bonding layer in which a through hole is formed in an embodiment of the present invention,

FIG. 12(d) is an essential portion sectional view of a multilayer wiring board in which a blind via hole is formed in an embodiment of the present invention,

FIG. 12(e) is an essential portion sectional view of a double-sided wiring board after a copper-core solder ball is press-fitted in a deformed manner in an embodiment of the present invention, and

FIG. 12(f) is an essential portion sectional view of a multilayer wiring board after an interlayer connection is made by forming a metallic film made of copper nanoparticles in an embodiment of the present invention; and

FIG. 13(a) is an essential portion sectional view of a multilayer wiring board after being laminated in an embodiment of the present invention, and FIG. 13(b) is an essential portion sectional view of another multilayer wiring board after being laminated in an embodiment of the present invention.

### DETAILED DESCRIPTION

### Embodiment 1

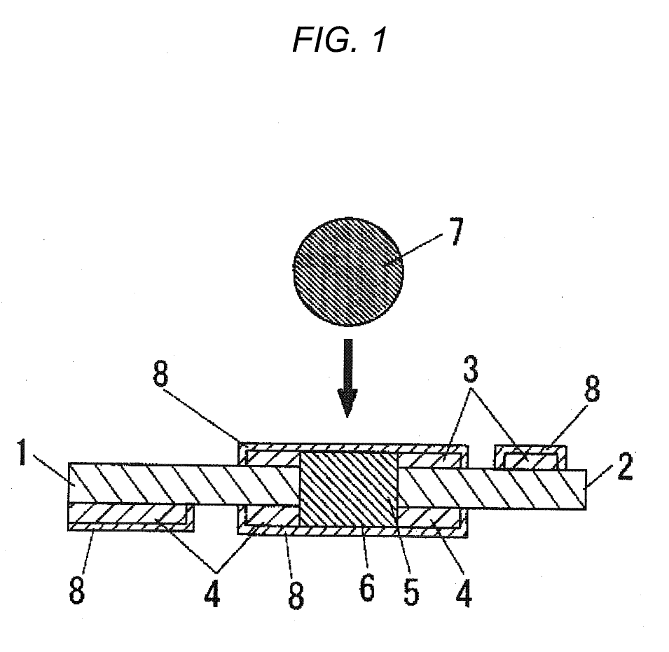

Hereinafter, a first embodiment of the present invention will be described with reference to FIG. 1 to FIG. 4. In these figures, identical members are attached with the same reference numeral, and overlapping description is omitted. The values shown in the embodiment are examples of variously selected values, and values are not limited to the values shown.

Hereinafter, a multilayer wiring board of an embodiment of the present invention will be described. First, a multilayer wiring board of the present invention is described with reference to FIG. 1. FIG. 1 is an essential portion sectional view of a multilayer wiring board of an embodiment of the present invention. In an embodiment of the present invention, a multilayer wiring board using an electric insulating film is mainly described, and a multilayer wiring board using a glass epoxy substrate is also basically similar, so that detailed description thereof is not given here.

In FIG. 1, the reference numeral 1 denotes a multilayer wiring board having a copper wiring upper layer 3 and a copper wiring lower layer 4 formed on both surfaces of an insulating layer 2 formed of a polyimide film, and interlayer connection between the copper wiring layers is made by a solder conductor 6 filled inside the through hole 5. Here, the solder conductor 6 is formed by pressure-deforming and filling the solder ball 7 in the thickness direction of the insulating layer 2. Further, the surfaces of the filled solder conductor 6 and the surfaces of the copper wiring layers are coated with plating films 8.

As shown in FIG. 1, the solder conductor 6 which makes interlayer connection between the multilayer wiring board 1 can be formed so that the solder ball 7 comes into close contact with the inside of the through hole 5 without gaps by press-fitting the solder ball 7 in a deformed manner, and is joined to the copper wiring upper layer 3 and the copper wiring lower layer 4. Further, the surfaces of the solder conductor 6 and the surfaces of the copper wiring layers are coated and integrated by the plating films 8, and the plating films 8 restrict the solder conductor 6 which expands when heating, whereby a structure which suppresses thermal stresses is obtained.

Here, the plating films 8 are made of a metal whose ionization tendency is greater than that of solder. The reason why the metal with an ionization tendency greater than that of solder is used is that, in the present invention, it is electrodeposited on metal surfaces of solder and copper whose ionization tendencies are different from each other, and in the case of immersion in a normal acid plating solution, a local cell is immediately formed between solder and copper, and solder with greater ionization tendency melts and corrodes. To suppress this solder corrosion, by performing electrodeposition in a plating solution in which a metal with an ionization tendency greater than that of solder is dissolved, the plating film can be formed while corrosion due to solder ionization is prevented, and as a result, coating by only the plating films with an ionization tendency greater than that of the solder conductor is possible. Solder used herein is tin or a tin alloy mainly composed of tin, and in other words, coating by only metal plating films with an ionization tendency greater than that of tin is possible.

Accordingly, the biggest problem in use of solder for an interlayer connection, in which if a conductor made of only solder is heated, solder in the through hole expands more than the insulating layer, the joint interface between the copper wiring layer and solder on the surface of the insulating layer separates, and reliability in connection by heat cannot be secured, is solved. Therefore, this structure provides high connection reliability.

As the solder conductor 6, a copper-core solder ball which has a copper piece smaller than the through hole 5 in its core, and whose surface is coated by a solder metal layer, may be filled. In this case, copper with excellent consistency in the thermal expansion coefficient with the insulating layer 2 is included in the core of the solder conductor 6, so that the thermal expansion coefficient of the entire solder conductor 6 can be optimized, and thermal stresses caused by a thermal expansion difference can be reduced, and higher connection reliability is obtained. Either of the solder conductors described above may be used as appropriate. As solder composition of the solder conductor 6, any of eutectic solder, high-temperature solder, lead-free solder, etc., may be used.

As the insulating layer 2, electrical insulating films such as a polyimide film, a PET (polyethylene terephthalate) film, a PEN (polyethylene naphthalate) film, a polyester film, a polyamide-imide film, a PEI (polyether imide) film, a PEEK (polyether etherketon) film, a PES (polyether sulfone) film, a PPS (polyphenylene sulfide) film, an aramid film, an LCP film, a PTFE (polytetrafluoroethylene) film, etc., can be used, and any of these can be used as appropriate. Among these, a polyimide film that has excellent heat resistance, dimensional stability, and machinability is most preferably used. Further, when a glass epoxy base material is used as the insulating layer 2, as a thermosetting resin, a phenol resin, a melamine resin, a polyester resin, a diallyphthalate resin, and an epoxy resin, and a resin material containing modified resins of these resins can be used, and in this thermosetting resin, paper, fiber, glass fiber, and unwoven fabric (any of synthetic, natural, inorganic, and organic fibers) may be used, and any of these can be used as appropriate.

As the plating film 8 with an ionization tendency greater than that of solder, nickel, a nickel alloy, zinc, and a zinc-based alloy may be used, and use of at least one of nickel and a nickel alloy is most preferable. The reason for this is that, by using nickel or a nickel alloy which are comparatively hard among metal materials, as the plating film 8, stresses of the solder conductor 6 whose metal plating films are thermally expanded can be reliably suppressed, and higher connection reliability is obtained.

Further, a different metal plating film may be formed on the surface of the plating film 8. This different metal plating film is formed on the surface of the plating film 8 that protectively coats the surface of the solder conductor 6 and the surface of each copper wiring layer, so that the plating film 8 serves as a barrier layer, and can be selected among normal plating metals without constraints by an ionization tendency. Therefore, plating coating on the surface can be selected according to the product, and the degree of freedom of the design of the product can be increased. Here, as the different metal plating film, silver, palladium, tin, copper, and alloys of these, etc., can be used, and any of these can be used as appropriate.

The plating film 8 may be partially plated on only the regions including the interlayer connecting portion. The coating of the plating films 8 limited to these ranges does not influence the copper wiring layers in process at all because the plating films 8 are not formed on the rest of the copper wiring layer surfaces, so that a structure preferable for miniaturizing the copper wiring layers is obtained. Therefore, a multilayer wiring board that is excellent in miniaturization of copper wiring layers and has high connection reliability is obtained.

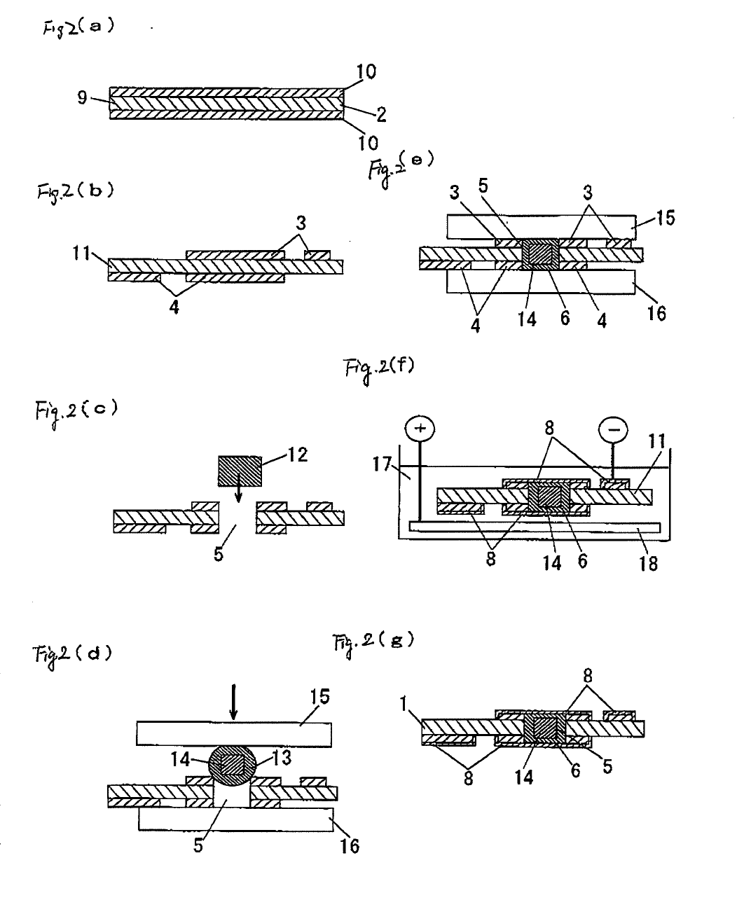

Next, a method for producing such a multilayer wiring board having high connection reliability by using a copper-core solder ball will be described with reference to FIG. 2 to FIG. 4. The reference numerals that are the same as those in FIG. 1 basically indicate the same components even in FIG. 2 to FIG. 4, so that description of these is omitted herein.

First, a method for producing a multilayer wiring board of an embodiment of the present invention will be described with reference to FIG. 2. FIG. 2(a) is an essential portion sectional view of a double-sided copper-clad lamination board which is a raw material in an embodiment of the present invention, FIG. 2(b) is an essential portion sectional view of a double-sided wiring board on which copper wiring layers are formed in an embodiment of the present invention, FIG. 2(c) is an essential portion sectional view of the double-sided wiring board in which a through hole is formed in an embodiment of the present invention, FIG. 2(d) is an essential portion sectional view of the double-sided wiring board before a copper-core solder ball is press-fitted in an embodiment of the present invention, FIG. 2(e) is an essential portion sectional view of the double-sided wiring board after the copper-core solder ball is press-fitted in a deformed manner in an embodiment of the present invention, FIG. 2(f) is an essential portion sectional view of the double-sided wiring board during formation of plating films in an embodiment of the present invention, and FIG. 2(g) is an essential portion sectional view of the multilayer wiring board after an interlayer connection is made in an embodiment of the present invention.

In FIG. 2, the reference numeral 9 denotes a double-sided copper-clad lamination board having copper foils directly formed on both surfaces of an insulating layer 2, and the reference numeral 11 denotes a double-sided wiring board on which copper wiring layers are formed by etching the double-sided copper-clad lamination board 9. The reference numeral 12 denotes a punching die for machining a through hole. The reference numeral 13 denotes a copper-core solder ball having a copper piece in its core. The reference numerals 15 and 16 denote a pressurizing upper plate and a pressurizing lower plate for press-fitting the copper-core solder ball 13 in a deformed manner. The reference numeral 17 denotes a plating bath for forming plating films 8, and the reference numeral 18 denotes a counter electrode for plating.

First, as shown in FIG. 2(a), the double-sided copper-clad lamination board 9 having copper foils 10 directly formed on both surfaces of the insulating layer 2 is prepared. In an embodiment of the present invention, a two-layer type having no bonding layer between the insulating layer 2 and the copper foils 10 is shown, however, a three-layer type including a bonding layer may also be used, and either of these can be used as appropriate, and the type is not limited to these.

Next, as shown in FIG. 2(b), a mask material is formed on the surfaces of the copper foils 10 and etching is performed by using a copper etchant such as iron chloride or copper chloride, whereby a double-sided wiring board 11 on which a copper wiring upper layer 3 and a copper wiring lower layer 4 are formed is obtained.

Further, as shown in FIG. 2(c), by punching by using a punching die 12, a through hole 5 is formed. In a first embodiment of the present invention, punching is used, however, depending on the type of the insulating layer 2 and the size and accuracy of the through hole, drilling, laser machining, and etching can also be used, and any of these can be used as appropriate, and the method is not limited to these.

Further, as shown in FIG. 2(d), after the copper-core solder ball 13 having the copper piece 14 in its core is disposed at the position of the through hole 5, press-fitting in a deformed manner of the copper-core solder ball 13 into the through hole 5 is started by the pressurizing upper plate 15 and the pressurizing lower plate 16. As a method for disposing the copper-core solder ball 13, a conventionally known method in which solder balls are mounted on a semiconductor package called BGA can be diverted. In detail, an adsorption plate provided with a suction hole with a diameter smaller than the copper-core solder ball 13 at a position corresponding to the through hole 5 is prepared, and is connected to a vacuum pump for adjustment of the pressure inside the suction hole. The copper-core solder ball 13 is suctioned into the suction hole by using the suction plate, and positioned above the through hole 5, and the copper-core solder ball 13 is dropped and disposed at the through hole position. Equipment called a ball mounter that performs these operations may be used. Here, an example of mounting of the copper-core solder ball 13 by means of vacuum adsorption is shown, however, other methods such as electrostatic adsorption can also be used.

Next, as shown in FIG. 2(e), the copper-core solder ball 13 is press-fitted in a deformed manner into the through hole 5 by the pressurizing upper plate 15 and the pressurizing lower plate 16, whereby a solder conductor 6 filled in the through hole 5 is formed. Here, the copper-core solder ball 13 is made of a soft metal of a solder alloy, so that it is successively deformed when it is press-fitted, and deformed along the inner wall of the through hole 5, and the inside of the through hole 5 can be completely filled with the solder conductor 6 without gaps. This solder conductor 6 makes electric continuity between the copper wiring upper layer 3 and the copper wiring lower layer 4.

Further, as shown in FIG. 2(f), the double-sided wiring board 11 in which the solder conductor 6 is filled is immersed in plating bath 17 and electrically energized by using the counter electrode 18 to form plating films 8 made of a metal whose ionization tendency is great on solder exposed surfaces on which a part of the solder conductor 6 is exposed to the outermost surfaces and the surfaces of the copper wiring layers, and as shown in FIG. 2(g), a multilayer wiring board 1 with high connection reliability in which electric continuity between the copper wiring layers is made by the solder conductor 6 filled in the through hole 5 and the surfaces of the solder conductor 6 having a copper piece 14 in its core and surfaces of the copper wiring layers are coated by the plating films 8, is obtained.

Here, the plating films 8 does not aim at performing a role as electric wiring as in the conventional plating through hole method but are for restriction of the thermally expanded solder conductor 6, so that the plating films can be made thinner in film thickness than in the plating through hole method. Therefore, in the production method, plating films are formed thinly for an interlayer connection after the copper wiring layers are formed, so that the plating films have less influence on the copper wiring layers, and are suitable for miniaturization of the copper wiring layers. Further, a partial plating method can also be used in which masking including exposure of the vicinities of the interlayer connecting portion is applied before forming the plating films 8 so that the plating films 8 are prevented from being formed on the rest of the copper wiring layer surfaces. According to this method, the plating films 8 are not formed on the rest of the copper wiring layer surfaces, so that this is more suitable for miniaturization of the copper wiring layers.

In the form of the production according to this production method, a plurality of products can be arranged on a hoop-like or sheet-like raw material and subjected to the respective processes, and the product external forms are cut out in the final process. Particularly, roll to roll method is a production form with excellent productivity, and is most preferable.

The method for producing a multilayer wiring board of an embodiment of the present invention obtained as described above has the following features. First, the surfaces of the interlayer connecting solder conductor and the copper wiring layers are coated by plating films so as to have an integrated structure, so that stresses caused by a thermal expansion difference can be suppressed and high connection reliability is obtained. Further, the thin plating films for an interlayer connection are formed after the copper wiring layers are formed, so that the plating films have less influence on the copper wiring layers, and are suitable for miniaturization of the copper wiring layers. Last, interlayer connection can be made by extremely simple processes of solder ball filling and metal plating, and in comparison with other interlayer connection methods, the number of processes is smaller and the productivity is remarkably improved. Therefore, according to the present invention, a multilayer wiring board having an interlayer connection that has high connection reliability and is suitable for miniaturization of the copper wiring layers and has excellent productivity is obtained.

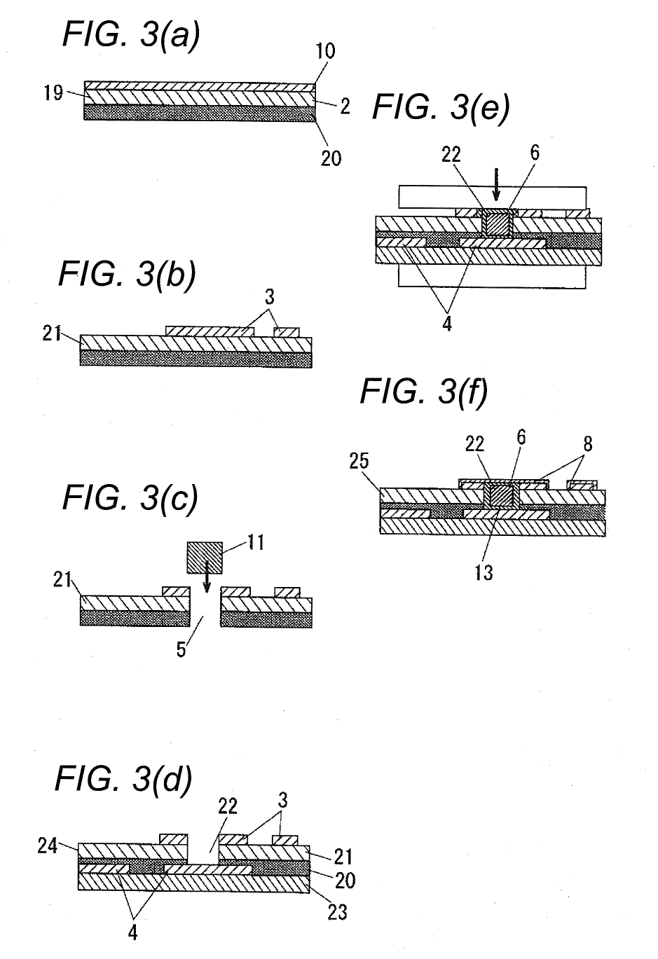

Next, a method for producing a multilayer wiring board of an embodiment of the present invention which is more excellent in connection reliability and miniaturization of copper wiring layers will be described with reference to FIG. 3. FIG. 3(a) is an essential portion sectional view of a one-sided copper-clad lamination board with a bonding layer as a raw material in an embodiment of the present invention, FIG. 3(b) is an essential portion sectional view of a one-sided wiring board with a bonding layer on which a copper wiring layer is formed in an embodiment of the present invention, FIG. 3(c) is an essential portion sectional view of the one-sided wiring board with a bonding layer in which a through hole is formed in an embodiment of the present invention, FIG. 3(d) is an essential portion sectional view of a multilayer wiring board in which a blind via hole is formed in an embodiment of the present invention, FIG. 3(e) is an essential portion sectional view of a double-sided wiring board after a copper-core solder ball is press-fitted in a deformed manner in an embodiment of the present invention, and FIG. 3(f) is an essential portion sectional view of a multilayer wiring board after an interlayer connection is made by forming a plating film in an embodiment of the present invention.

In FIG. 3, the reference numeral 19 denotes a one-sided copper-clad lamination board with a bonding layer that has a copper foil 10 formed on one surface of the insulating layer 2 and a bonding layer 20 formed on the other surface. 21 denotes a one-sided wiring board with a bonding layer obtained by forming a copper wiring upper layer 3 by etching the one-sided copper-clad lamination board 19 with a bonding layer. The reference numeral 23 denotes another one-sided wiring board to be laminated on the one-sided wiring board 21 with a bonding layer. The reference numeral 24 denotes a multilayer wiring board that has a blind via hole 22 for an interlayer connection formed by laminating the one-sided wiring boards 21 and 23 with a bonding layer. 25 denotes a multilayer wiring board which has a solder conductor 6 filled in the blind via hole 22 and a plating film 8 which coats and integrates the surface of the solder conductor 6 and the surface of the copper wiring upper layer 3.

First, as shown in FIG. 3(a), the one-sided copper-clad lamination board 19 with a bonding layer which has the copper foil 10 directly formed on one surface of the insulating layer 2 and a bonding layer 20 formed on the other surface is prepared, and as shown in FIG. 3(b), the copper wiring upper layer 3 is formed by etching, whereby a one-sided wiring board 21 with a bonding layer is obtained. The copper wiring upper layer 3 of the one-sided wiring board 21 with a bonding layer obtained herein can be subjected to one-side etching suitable for miniaturization, so that it can be further miniaturized in comparison with the copper wiring layers of the double-sided wiring board described above.

The reason for this is described as follows. Normally, in formation of the copper wiring layers of the double-sided wiring board, to simultaneously etch copper foils on both surfaces of the double-sided copper-clad lamination board, an etchant must be applied uniformly from the upper and lower sides of the double-sided copper-clad lamination board. However, when an etchant is pressure-sprayed from the upper and lower sides of the double-sided copper-clad lamination board, the etchant sprayed on the upper surface forms an etchant pool on the upper surface and the etchant cannot be maintained uniform. Therefore, on the double-sided wiring board, etching conditions become unstable and it is difficult to form very minute copper wiring layers. On the other hand, in formation of the copper wiring layer of the one-sided wiring board, the etchant is sprayed from the lower side, so that a pool of the etchant is not formed, and optimum ranges of etching conditions become wide, and this is suitable for miniaturization of the copper wiring layer.

Next, as shown in FIG. 3(c), the one-sided wiring board 21 with a bonding layer is subjected to punching by using a punching die 12 to form a through hole 5, and as shown in FIG. 3(d), the one-sided wiring board 21 with a bonding layer and another one-sided wiring board 23 on which a copper wiring lower layer 4 is formed are bonded via the bonding layer 20, whereby a multilayer wiring board 24 in which a blind via hole 22 for an interlayer connection is formed is obtained. The multilayer wiring board 24 obtained herein is formed by laminating one-sided wiring boards having minute copper wiring layers, so that in comparison with the wiring layers of the double-sided wiring board, the copper wiring layers become more minute. As a method for laminating the one-sided wiring boards in an embodiment of the present invention, the multilayer wiring board 24 is shown, however, even when a double-sided wiring board is formed by bonding two one-sided wiring boards together via a bonding layer so that their copper wiring layers become the outermost layers, the copper wiring layers can be miniaturized. Either of the lamination methods can be used as an appropriate method, and the method is not limited to these.

Further, as shown in FIG. 3(e), a copper-core solder ball is press-fitted in a deformed manner into the blind via hole 22 to form a solder conductor 6. The solder conductor 6 obtained herein is filled in the blind via hole 22 which has the copper wiring lower layer 4 on its bottom surface, so that in comparison with the through hole, the joining area between the solder conductor 6 and the copper wiring lower layer 4 increases, and the adhesion strength between these also increases. Therefore, even when various external stresses are applied, the joint interface between the copper wiring lower layer 4 and the solder conductor 6 does not separate, and higher connection reliability is obtained.

Last, as shown in FIG. 3(f), by electrodeposition of plating bath, a plating film 8 made of a metal having great ionization tendency is formed on a solder exposed surface on which a part of the solder conductor 6 is exposed to the outermost surface and the surface of the copper wiring upper layer 3, electric continuity between the copper wiring layers is made by the solder conductor 6 filled in the blind via hole 22, whereby a multilayer wiring board 25 in which the surface of the solder conductor 6 having the copper piece 14 in its core and the surface of the copper wiring layer is coated and integrated by the plating film 8 is obtained.

According to the method for producing a multilayer wiring board in an embodiment of the present invention obtained as described above, one-sided wiring boards are laminated, so that in comparison with copper wiring layers of a double-sided wiring board, the copper wiring layers become more minute. Further, a solder conductor is filled in the blind via hole by press-fitting a copper-core solder ball in a deformed manner, so that in comparison with the through hole, higher connection reliability is obtained. Therefore, according to the present invention, a multilayer wiring board having an interlayer connection that has high connection reliability and is optimum for miniaturization of the copper wiring layers, and has excellent productivity is obtained.

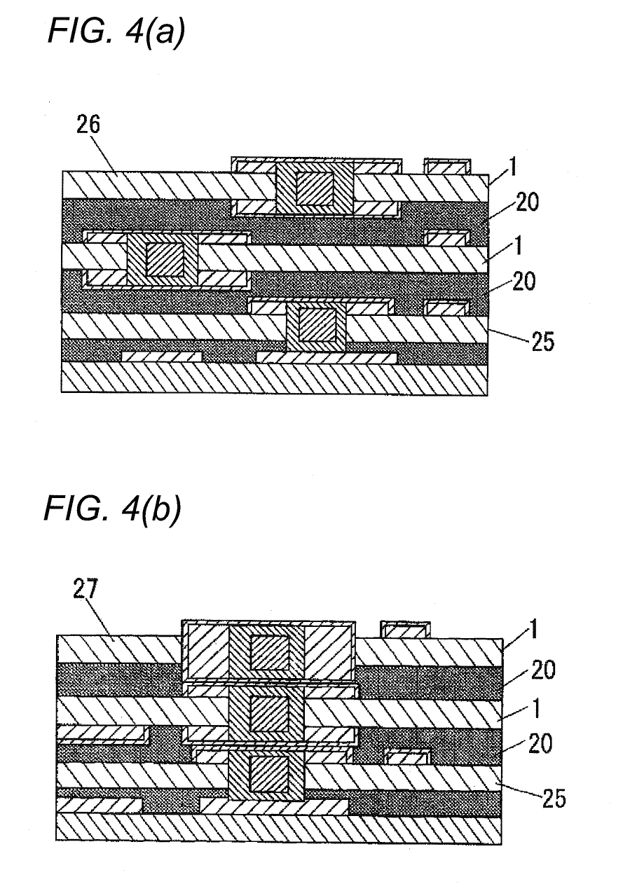

Finally, a multilayer wiring board of an embodiment of the present invention in which more multilayer wiring boards described above are laminated will be described with reference to FIG. 4. FIG. 4(a) is an essential portion sectional view of a multilayer wiring board after being laminated in an embodiment of the present invention, and FIG. 4(b) is an essential portion sectional view of another multilayer wiring board after being laminated in an embodiment of the present invention.

In FIG. 4, the reference numeral 26 denotes a multilayer wiring board formed by laminating a multilayer wiring board 1 and a multilayer wiring board 25 via a bonding layer 20. First, as shown in FIG. 4(a), the multilayer wiring board 1 and the multilayer wiring board 25 produced according to an embodiment of the present invention described above are further laminated via the bonding layer 20, whereby a multilayer wiring board 26 including an increased number of copper wiring layers is obtained. In the multilayer wiring board 26 obtained herein, the multilayer wiring board 1 and the multilayer wiring board 25 which are components have high connection reliability and minute copper wiring layers, so that the multilayer wiring board 26 has high connection reliability and is excellent in miniaturization of copper wiring layers.

As shown in FIG. 4(b), a multilayer wiring board 27 is obtained by laminating the multilayer wiring board 1 and the multilayer wiring board 25 so that their plating films 8 come into contact with each other. Here, the plating films 8 are metal layers, so that electric continuity between the wiring layers can be made. When solder plating films are further laminated on the surfaces of the plating films 8, by bringing these solder plating films into contact with each other and heating and cooling these, the solder plating films are molten and solidified, and the solder plating films are easily joined to each other and improved in connection reliability.

The multilayer wiring board in an embodiment of the present invention obtained as described above is formed by further laminating multilayer wiring boards which have high connection reliability and minute copper wiring layers, so that it has high connection reliability and is excellent in miniaturization of copper wiring layers. Therefore, according to the present invention, a multilayer wiring board having an interlayer connection which has high connection reliability and is optimum for miniaturization of the copper wiring layers and excellent in productivity is obtained.

The present invention provides a multilayer wiring board having an interlayer connection that has high connection reliability and is optimum for miniaturization of copper wiring layers and has excellent productivity, and a method for producing the same.

### Embodiment 2

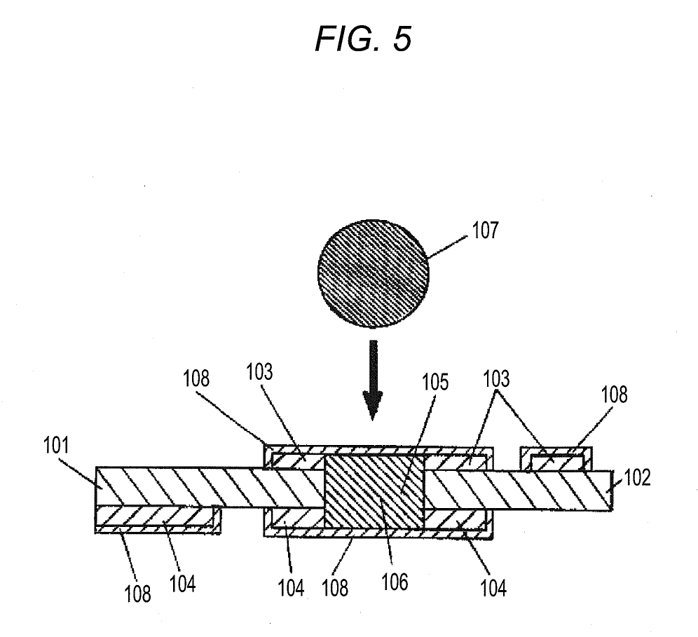

Hereinafter, a second embodiment of the present invention will be described with reference to FIG. 5 to FIG. 9. In these figures, identical members are attached with the same reference numeral, and overlapping description is omitted. The values shown in the embodiment are examples of variously selected values, and values are not limited to the values shown.

Hereinafter, a multilayer wiring board of an embodiment of the present invention will be described. First, a multilayer wiring board of the present invention is described with reference to FIG. 5. FIG. 5 is an essential portion sectional view of a multilayer wiring board of an embodiment of the present invention. In an embodiment of the present invention, a multilayer wiring board using an electric insulating film is mainly described, and a multilayer wiring board using a glass epoxy substrate is also basically similar, so that detailed description thereof is not given here.

In FIG. 5, the reference numeral 101 denotes a multilayer wiring board having a copper wiring upper layer 103 and a copper wiring lower layer 104 formed on both surfaces of an insulating layer 102 formed of a polyimide film, and interlayer connection between the copper wiring layers is made by a solder conductor 106 filled inside the through hole 105. Here, the solder conductor 106 is formed by press-fitting and filling one substantially spherical solder ball 107 in a deformed manner into the through hole 105 without gaps. Further, the surfaces of the filled solder conductor 106 and the surfaces of the copper wiring layers are coated and integrated by copper plating films 108.

As shown in FIG. 5, the solder conductor 106 which makes interlayer connection of the multilayer wiring board 101 can be formed by press-fitting in a deformed manner the solder ball 107 so that the solder ball 107 comes into contact with the inside of the through hole 105 without gaps, and is joined to the copper wiring upper layer 103 and the copper wiring lower layer 104. Further, the surfaces of the solder conductor 106 and the surfaces of the copper wiring layers are coated and integrated by the copper plating films 108, and these copper plating films 108 restrict the solder conductor 106 which expands when heating, whereby a structure which suppresses thermal stresses is obtained.

Here, the copper plating films 108 are formed of copper plating films 108 electrodeposited by alkaline copper plating. In the electrodeposition on metal surfaces of solder and copper which are different in ionization tendency from each other, when they are immersed in a normal acid copper plating solution, a local cell is immediately formed between solder and copper, and solder with greater ionization tendency melts and corrodes. To suppress this solder corrosion, by performing electrodeposition in an alkaline copper plating solution, copper plating films 8 can be formed on the surfaces while preventing corrosion due to ionization of solder, and as a result, integral coating and joining are realized only by electrodeposition of alkaline copper plating.

Accordingly, the biggest problem in use of solder for an interlayer connection, in which if a conductor made of only solder is heated, solder in the through hole expands more than the insulating layer, the joint interface between the copper wiring layer and solder on the surface of the insulating layer separates, and reliability in connection by heat cannot be secured, is solved. Therefore, this structure provides high connection reliability.

As the solder conductor 106, a copper-core solder ball that has a copper piece smaller than the through hole 105 in its core, and whose surface is coated with a solder metal layer, may be filled. In this case, copper with excellent consistency in the thermal expansion coefficient with the insulating layer 102 is included in the core of the solder conductor 106, so that the thermal expansion coefficient of the entire solder conductor can be optimized, and thermal stresses caused by a thermal expansion difference can be reduced, and higher connection reliability is obtained. Either of the solder conductors described above may be used as appropriate. As solder composition of the solder conductor 106, any of eutectic solder, high-temperature solder, lead-free solder, etc., may be used.

As the insulating layer 102, electric insulating films such as a polyimide film, a PET (polyethylene terephthalate) film, a PEN (polyethylene naphthalate) film, a polyester film, a polyamide-imide film, a PEI (polyether imide) film, a PEEK (polyether etherketon) film, a PES (polyether sulfone) film, a PPS (polyphenylene sulfide) film, an aramid film, an LCP film, a PTFE (polytetrafluoroethylene) film, etc., can be used, and any of these can be used as appropriate. Among these, a polyimide film which has excellent heat resistance, dimensional stability, and machinability is most preferably used. Further, when a glass epoxy base material is used as the insulating layer 102, as a thermosetting resin, a phenol resin, a melamine resin, a polyester resin, a diallyphthalate resin, and an epoxy resin, and a resin material containing modified resins of these resins can be used, and in this thermosetting resin, paper, fiber, glass fiber, and unwoven fabric (any of synthetic, natural, inorganic, and organic fibers) may be used, and any of these can be used as appropriate.

As the plating film to be electrodeposited in an alkaline plating solution, gold, silver, palladium, copper, tin, zinc, and alloys of these can be used, and copper or a copper alloy is most preferably used. The reason for this is that, in the etching process of the production method described later, copper plating films which are the same metal as the copper foils are formed on the entire surfaces of the copper foils, so that copper wiring layers can be formed by one etching process, and accordingly, high productivity is secured.

Further, the copper plating film 108 may be partially plated on regions including the interlayer connecting portion. The coating of the copper plating films 108 limited to these ranges does not influence the copper wiring layers in process at all because the copper plating films 108 are not formed on the rest of the copper wiring layer surfaces, so that a structure preferable for miniaturizing the copper wiring layers is obtained. Therefore, a multilayer wiring board that has further excellently miniaturized copper wiring layers and higher connection reliability is obtained.

Next, a method for producing such a multilayer wiring board having high connection reliability in the case of using a copper-core solder ball will be described in detail with reference to FIG. 6 to FIG. 9. The reference numerals that are the same as those in FIG. 5 basically indicate the same components even in FIG. 6 to FIG. 9, so that description of these is omitted herein. First, a method for producing a multilayer wiring board of an second embodiment of the present invention will be described with reference to FIG. 6.

FIG. 6(a) is an essential portion sectional view of a double-sided copper-clad lamination board which is a raw material in an embodiment of the present invention, FIG. 6(b) is an essential portion sectional view of the double-sided wiring board in which a through hole is formed in an embodiment of the present invention, FIG. 6(c) is an essential portion sectional view of the double-sided wiring board before a copper-core solder ball is press-fitted in an embodiment of the present invention, FIG. 6(d) is an essential portion sectional view of the double-sided wiring board after the copper-core solder ball is press-fitted in a deformed manner in an embodiment of the present invention, FIG. 6(e) is an essential portion sectional view of the double-sided wiring board during formation of copper plating films in an embodiment of the present invention, and FIG. 6(f) is an essential portion sectional view of the multilayer wiring board on which copper wiring layers having an interlayer connection made therebetween are formed in an embodiment of the present invention.

In FIG. 6, the reference numeral 109 denotes a double-sided copper-clad lamination board having copper foils 110 directly formed on both surfaces of an insulating layer 102, and the reference numeral 111 denotes a punching die for machining a through hole. The reference numeral 112 denotes a substantially spherical copper-core solder ball having a copper piece in its core. The reference numerals 114 and 115 denote a pressurizing upper plate and a pressurizing lower plate for press-fitting the copper-core solder ball 112 in a deformed manner. The reference numeral 116 denotes an alkaline plating bath for forming copper plating films 108, and the reference numeral 117 denotes a counter electrode for copper plating.

First, as shown in FIG. 6(a), the double-sided copper-clad lamination board 109 having copper foils 110 directly formed on both surfaces of the insulating layer 102 is prepared. In an embodiment of the present invention, a two-layer type having no bonding layer between the insulating layer 102 and the copper foils 110 is shown, however, a three-layer type including a bonding layer may also be used, and either of these can be used as appropriate, and the type is not limited to these.

Next, as shown in FIG. 6(b), by punching by using a punching die 11a through hole 105 is formed. In an second embodiment of the present invention, punching is used, however, depending on the type of the insulating layer 102 and the size and accuracy of the through hole, drilling, laser machining, and etching can also be used, and any of these can be used as appropriate, and the method is not limited to these.

Further, as shown in FIG. 6(c), after the copper-core solder ball 112 having the copper piece 113 in its core is disposed at the position of the through hole 105, press-fitting in a deformed manner of the copper-core solder ball 112 into the through hole 105 is started by the pressurizing upper plate 114 and the pressurizing lower plate 115. As a method for disposing the copper-core solder ball 112, a conventionally known method in which solder balls are mounted on a semiconductor package called BGA can be diverted. In detail, an adsorption plate provided with a suction hole with a diameter smaller than the copper-core solder ball at a position corresponding to the through hole 105 is prepared, and is connected to a vacuum pump for adjustment of the pressure inside the suction hole. The copper-core solder ball is suctioned into the suction hole by using the suction plate, and positioned above the through hole 105, and the copper-core solder ball 112 is dropped and disposed at the through hole position. Equipment called a ball mounter that performs these operations may be used. Here, an example of mounting of the copper-core solder ball by means of vacuum adsorption is shown, however, other methods such as electrostatic adsorption can also be used.

Further, as shown in FIG. 6(d), the copper-core solder ball 112 is press-fitted in a deformed manner into the through hole 105 by the pressurizing upper plate 114 and the pressurizing lower plate 115, whereby a solder conductor 106 filled in the through hole 105 is formed. Here, the surface layer of the copper-core solder ball 112 is made of a soft metal of a solder alloy, so that it is successively deformed when it is press-fitted, and deformed along the inner wall of the through hole 105, and the inside of the through hole 105 can be completely filled with the solder conductor 106 without gaps. This filled solder conductor 106 makes electric continuity between the copper foils 110. Herein, a production method in which a copper-core solder ball is filled in the through hole to form the solder conductor 106 is shown, however, a substantially spherical solder ball which does not include a copper core can also be filled. In this case, the solder ball is made of only solder of a soft material, so that it is easily filled in the through hole, and the operability can be improved and the tact time can be shortened, and further, production with high productivity without deforming the wiring layers is possible. Either of the solder balls may be used as appropriate, and the solder ball is not limited to these.

Further, as shown in FIG. 6(e), the double-sided copper clad wiring board 109 in which the solder conductor 106 is filled is immersed in alkaline plating bath 116 and electrically energized by using the counter electrode 117 to electrodeposit copper plating films 108 on solder exposed surfaces on which a part of the solder conductor 106 is exposed to the outermost surfaces and the surfaces of the copper foils 110. As the alkaline copper-plating bath 116 to be used here, a pyrophosphate copper plating solution and a cyanogen-based copper plating solution that are alkaline can be used. Either of these may be used as appropriate, and the alkaline copper-plating bath is not limited to these.

Here, the copper plating films 108 are not for serving as electric wiring as in the conventional plating through hole method, but are for restricting the thermally expanded solder conductor, so that the copper plating films can be made thinner in film thickness than in the plating through hole method. Therefore, in the production method, the copper plating films are formed thinly on the entire surfaces of the copper foils including the surfaces of the solder conductor, so that they have less influence on copper wiring layers formed by subsequent etching, and are suitable for miniaturization of the copper wiring layers. Further, copper plating films which are the same metal as the copper foils are formed on the entire surfaces of the copper foils, so that copper wiring layers can be formed by one etching process, and high productivity can be secured.

Last, a mask material is formed on the surfaces of the copper foils 110 and etching is performed by using a copper etchant such as iron chloride or copper chloride, and electric continuity between the surface and back surface copper wiring layers is made by the solder conductor 106 filled in the through hole 105 and the copper plating films which coat and integrate the surfaces of the solder conductor 106 and the surfaces of the copper wiring layers, whereby a multilayer wiring board 101 with high connection reliability in which the surfaces of the solder conductor 106 having a copper piece 113 in its core and the surfaces of the copper wiring layers are coated and integrated by plating films 108, is obtained.

In the form of production according to this production method, a plurality of products can be arranged on a hoop-like or sheet-like raw material and subjected to the respective processes, and the product external forms can be cut out in the final process. Particularly, roll to roll method is a production form with excellent productivity, and is most preferable.

The method for producing a multilayer wiring board in an embodiment of the present invention obtained as described above has the following features. First, the surfaces of the solder conductor making interlayer connection and copper wiring layers are coated by copper plating films and have an integral structure, so that stresses caused by a thermal expansion difference can be suppressed and high connection reliability can be obtained. Further, on the entire surfaces of the copper foils including the surfaces of the solder conductor, copper plating films are thinly formed, so that the copper plating films have less influence on the copper wiring layers which are formed by subsequent etching, and this is suitable for miniaturization of the copper wiring layers. Last, the copper plating films which are the same metal as the copper foils are formed on the entire surfaces of the copper foils, so that the copper wiring layers can be formed by one etching process, and interlayer connection can be made by very simple processes of filling of a copper-core solder ball and copper plating, so that in comparison with other interlayer connection methods, the number of processes is smaller and the productivity is remarkably improved. Therefore, according to the present invention, a multilayer wiring board having an interlayer connection that has high connection reliability and is optimum for miniaturization of the copper wiring layers, and has excellent productivity, is obtained.

Next, a method for producing a multilayer wiring board in an embodiment of the present invention with higher connection reliability will be described with reference to FIG. 7. FIG. 7(a) is an essential portion sectional view of a double-sided copper-clad lamination board which is a raw material in an embodiment of the present invention, FIG. 7(b) is an essential portion sectional view of a double-sided wiring board on which copper wiring layers are formed in an embodiment of the present invention, FIG. 7(c) is an essential portion sectional view of the double-sided wiring board in which a through hole is formed in an embodiment of the present invention, FIG. 7(d) is an essential portion sectional view of the double-sided wiring board after the copper-core solder ball is press-fitted in a deformed manner in an embodiment of the present invention, and FIG. 7(e) is an essential portion sectional view of the multilayer wiring board after an interlayer connection is made by forming copper plating films in an embodiment of the present invention.

In FIG. 7, the reference numeral 118 denotes a double-sided wiring board on which copper wiring layers are formed by etching the double-sided lamination board 109.

First, as shown in FIG. 7(a), the double-sided copper-clad lamination board 109 having copper foils 110 directly formed on both surfaces of the insulating layer 102 is prepared, and as shown in FIG. 7(b), a mask material is formed on the surfaces of the copper foils 110 and etching is performed by using a copper etchant such as iron chloride or copper chloride, whereby a double-sided wiring board 118 on which a copper wiring upper layer 103 and a copper wiring lower layer 104 are formed is obtained.

Further, as shown in FIG. 7(c), a through hole 105 is formed by punching by using a punching die 111, and as shown in FIG. 7(d), and a copper-core solder ball is press-fitted in a deformed manner into the through hole 105 by the pressurizing upper plate 114 and the pressurizing lower plate 115 to form a solder conductor 106 filled in the through hole 105. This solder conductor 106 makes electric continuity between the copper wiring upper layer 103 and the copper wiring lower layer 104.

Last, as shown in FIG. 7(e), the copper plating films 108 are formed on the surfaces of the solder conductor 106 and the surfaces of the copper wiring layers by electrodeposition of alkaline copper plating bath, whereby a multilayer wiring board 101 in which the solder conductor 106 filled in the through hole 105 makes electric continuity between the copper wiring layers and the surfaces of the solder conductor 106 having a copper piece 113 in its core and the surfaces of the copper wiring layers are coated and integrated by the copper plating films 108, is obtained. In this multilayer wiring board 101, after the copper wiring layers are formed, the copper plating films 108 are formed and also coat the side surfaces of the copper wiring layers, so that the adhering areas of the copper plating films 108 increase, and the adhesion strengths of the copper plating films 108 to the copper wiring layers can be improved. Therefore, the solder conductor 106 which thermally expands in the interlayer connecting portion can be reliably suppressed, so that higher connection reliability is obtained.

Here, a partial plating method can also be used in which masking including exposure of the vicinities of the interlayer connecting portion is applied before forming the copper plating films 108 so that the copper plating films are prevented from being formed on the rest of the copper wiring layer surfaces. According to this method, the plating films are not formed on the rest of the copper wiring layer surfaces, so that this is more suitable for miniaturization of the copper wiring layers.

According to the method for producing a multilayer wiring board in an embodiment of the present invention obtained as described above, copper plating films formed after the copper wiring layers are formed are also coated on the side surfaces of the copper wiring layers, so that the adhesion strengths of the copper plating films can be improved, and the solder conductor 6 in the interlayer connecting portion can be reliably restricted, and accordingly, a multilayer wiring board with higher connection reliability is obtained. Therefore, according to the present invention, a multilayer wiring board with interlayer connection that has high connection reliability and is optimum for miniaturization of the copper wiring layers, and has excellent productivity, is obtained.

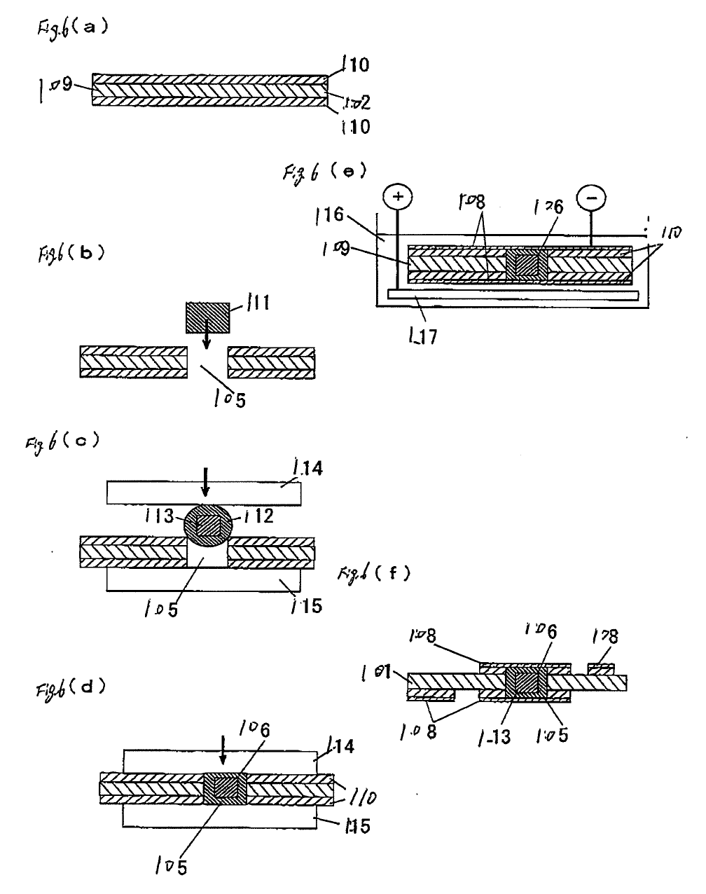

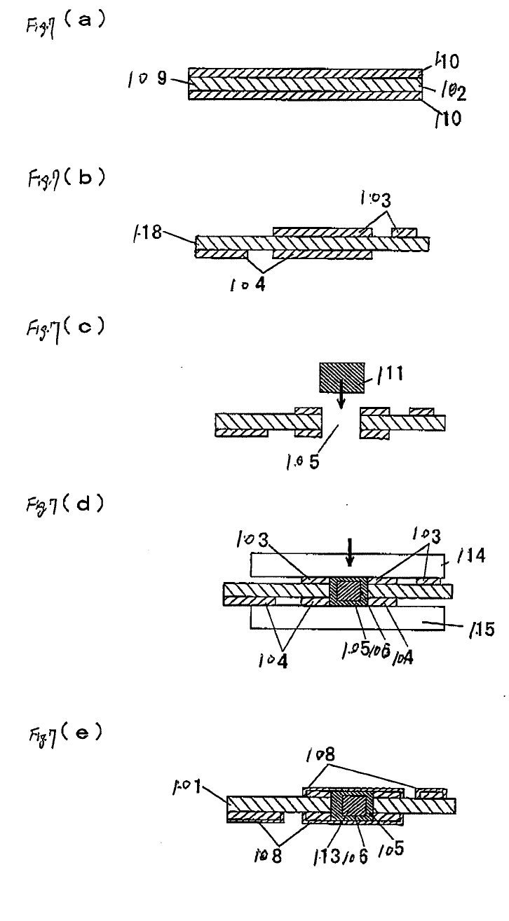

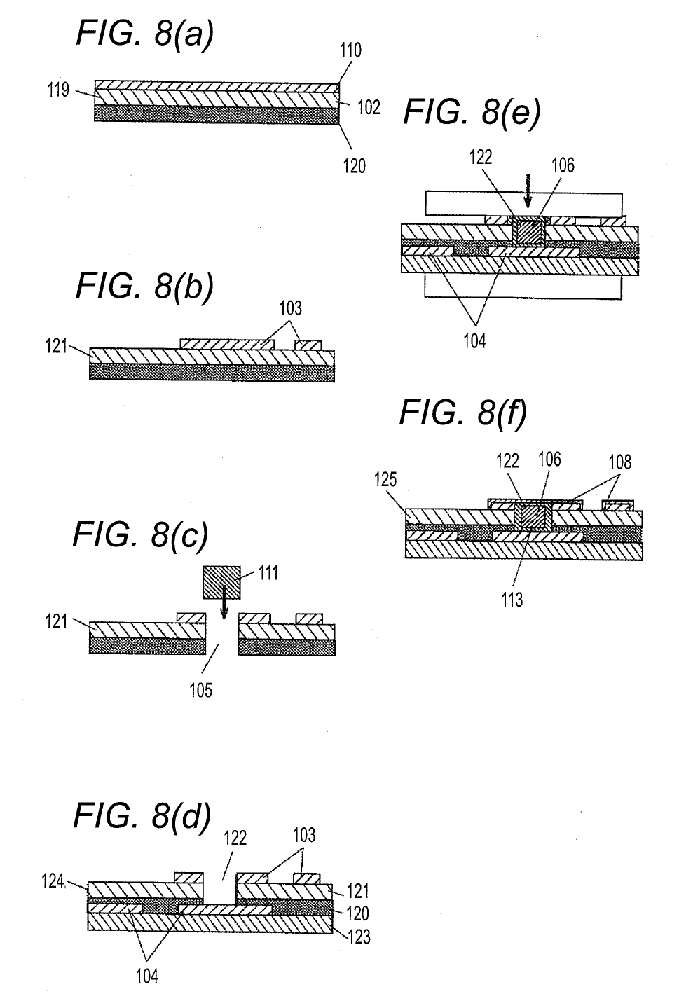

Next, a method for producing a multilayer wiring board in an embodiment of the invention which is more excellent in connection reliability and miniaturization of copper wiring layers will be described with reference to FIG. 8. FIG. 8(a) is an essential portion sectional view of a one-sided copper-clad lamination board with a bonding layer as a raw material in an embodiment of the present invention, FIG. 8(b) is an essential portion sectional view of a one-sided wiring board with a bonding layer on which a copper wiring layer is formed in a second embodiment of the present invention, FIG. 8(c) is an essential portion sectional view of the one-sided wiring board with a bonding layer in which a through hole is formed in an embodiment of the present invention, FIG. 8(d) is an essential portion sectional view of a multilayer wiring board in which a blind via hole is formed in an embodiment of the present invention, FIG. 8(e) is an essential portion sectional view of a double-sided wiring board after a copper-core solder ball is press-fitted in a deformed manner in an embodiment of the present invention, and FIG. 8(f) is an essential portion sectional view of a multilayer wiring board after an interlayer connection is made by forming a copper plating film in an embodiment of the present invention.

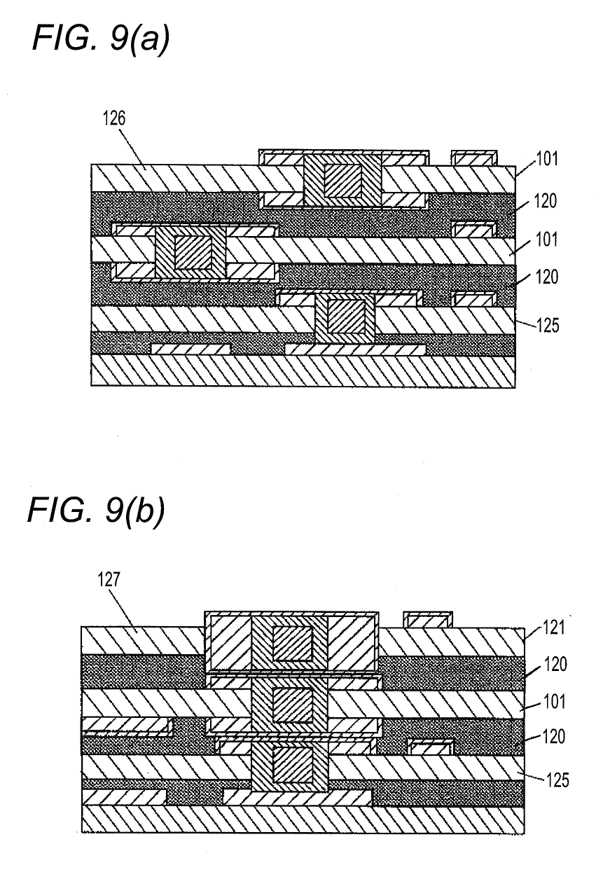

In FIG. 9, the reference numeral 119 denotes a one-sided copper-clad lamination board with a bonding layer that has a copper foil 110 formed on one surface and a bonding layer 120 formed on the other surface. The reference numeral 121 denotes a one-sided wiring board with a bonding layer obtained by forming a copper wiring upper layer 103 by etching the one-sided copper-clad lamination board 119 with a bonding layer. The reference numeral 123 denotes another one-sided wiring board to be laminated on the one-sided wiring board 121 with a bonding layer. The reference numeral 124 denotes a multilayer wiring board which has a blind via hole 122 for interlayer connection formed by laminating the one-sided wiring board with a bonding layer 121 and the one-sided wiring board 123. The reference numeral 125 denotes a multilayer wiring board which has a solder conductor 106 filled in the blind via hole 122 and a copper plating film 108 which coats and integrates the surface of the solder conductor 106 and the surface of the copper wiring upper layer 103.

First, as shown in FIG. 8(a), the one-sided copper-clad lamination board 109 with a bonding layer which has the copper foil 110 directly formed on one surface of the insulating layer 102 and a bonding layer 120 formed on the other surface is prepared, and as shown in FIG. 8(b), the copper wiring upper layer 103 is formed by etching, whereby a one-sided wiring board 121 with a bonding layer is obtained. The copper wiring upper layer 103 of the one-sided wiring board 121 with a bonding layer obtained herein can be subjected to one-side etching suitable for miniaturization, so that it can be further miniaturized in comparison with the copper wiring layers of the double-sided wiring board described above.

The reason for this is described as follows. Normally, in formation of the copper wiring layers of the double-sided wiring board, to simultaneously etch copper foils on both surfaces of the double-sided copper-clad lamination board, an etchant must be applied uniformly from the upper and lower sides of the double-sided copper-clad lamination board. However, when an etchant is pressure-sprayed from the upper and lower sides of the double-sided copper-clad lamination board, the etchant sprayed on the upper surface forms an etchant pool on the upper surface and the etchant cannot be maintained uniform. Therefore, on the double-sided wiring board, etching conditions become unstable and it is difficult to form very minute copper wiring layers. On the other hand, in formation of the copper-wiring layer of the one-sided wiring board, the etchant is sprayed from the lower side, so that a pool of the etchant is not formed, and optimum ranges of etching conditions become wide, and this is suitable for miniaturization of the copper-wiring layer.

Next, as shown in FIG. 8(c), the one-sided wiring board 121 with a bonding layer is subjected to punching by using a punching die 112 to form a through hole 105, and as shown in FIG. 8(d), the one-sided wiring board 121 with a bonding layer and another one-sided wiring board 123 on which a copper wiring lower layer 104 is formed are bonded via the bonding layer 120, whereby a multilayer wiring board 124 in which a blind via hole 122 for interlayer connection is formed is obtained. The multilayer wiring board 124 obtained herein is formed by laminating one-sided wiring boards having minute copper wiring layers, so that in comparison with the wiring layers of the double-sided wiring boards, the copper wiring layers become more minute. As a method for laminating the one-sided wiring boards in an embodiment of the present invention, the multilayer wiring board 124 is shown, however, even when a double-sided wiring board is formed by bonding two one-sided wiring boards together via a bonding layer so that their copper wiring layers become the outermost layers, the copper wiring layers can be miniaturized. Either of the lamination methods can be used as an appropriate method, and the method is not limited to these.

Further, as shown in FIG. 8(e), a copper-core solder ball is press-fitted in a deformed manner into the blind via hole 122 to form a solder conductor 106. The solder conductor 106 obtained herein is filled in the blind via hole 122 which has the copper wiring lower layer 104 on its bottom surface, so that in comparison with the through hole, the joining area between the solder conductor 106 and the copper wiring lower layer 104 increases, and the adhesion strength between these also increases. Therefore, even when various external stresses are applied, the joint interface between the copper wiring lower layer 104 and the solder conductor 106 does not separate, and higher connection reliability is obtained.

Last, as shown in FIG. 8(f), by electrodeposition of alkaline copper plating bath, a copper plating film 108 is formed on the surface of the solder conductor 106 and the surface of the copper wiring upper layer 103, whereby a multilayer wiring board 125 in which electric continuity between the copper wiring layers is made by a solder exposed surface on which a part of the solder conductor 106 filled in the blind via hole 122 is exposed to the outermost surface, and the surface of the solder conductor 106 having a copper piece 113 in its core and the surface of the copper wiring layer, are coated and integrated by the copper plating film 108, is obtained.

According to the method for producing a multilayer wiring board in an embodiment of the present invention obtained as described above, one-sided wiring boards are laminated, so that in comparison with copper wiring layers of a double-sided wiring board, the copper wiring layers become more minute.

Further, a solder conductor is filled in the blind via hole by press-fitting a copper-core solder ball in a deformed manner, so that in comparison with the through hole, higher connection reliability is obtained. Therefore, according to the present invention, a multilayer wiring board having an interlayer connection that has high connection reliability and is optimum for miniaturization of the copper wiring layers, and has excellent productivity is obtained.

Finally, a multilayer wiring board of an embodiment of the present invention in which multilayer wiring boards described above are further laminated will be described with reference to FIG. 9. FIG. 9(a) is an essential portion sectional view of a multilayer wiring board after being laminated in an embodiment of the present invention, and FIG. 9(b) is an essential portion sectional view of another multilayer wiring board after being laminated in an embodiment of the present invention.

In FIG. 9, the reference numeral 126 denotes a multilayer wiring board formed by laminating a multilayer wiring board 101 and a multilayer wiring board 125 via a bonding layer 120. First, as shown in FIG. 9(a), the multilayer wiring board 101 and the multilayer wiring board 125 produced according to a second embodiment of the present invention described above are further laminated via the bonding layer 120, whereby a multilayer wiring board 126 including an increased number of copper wiring layers is obtained. In the multilayer wiring board 126 obtained herein, the multilayer wiring board 101 and the multilayer wiring board 125 which are components have high connection reliability and minute copper wiring layers, so that the multilayer wiring board 126 has high connection reliability and is excellent in miniaturization of copper wiring layers.

As shown in FIG. 9(b), a multilayer wiring board 127 is obtained by laminating the multilayer wiring board 101 and the multilayer wiring board 125 so that their copper plating films 108 come into contact with each other. Here, the copper plating films 108 are metal layers, so that electric continuity between the wiring layers can be made. When solder plating films are further laminated on the surfaces of the copper plating films 108, by bringing these solder plating films into contact with each other and heating and cooling these, the solder plating films are molten and solidified, and the solder plating films are easily joined to each other and improved in connection reliability.

The multilayer wiring board in an embodiment of the present invention obtained as described above is formed by further laminating multilayer wiring boards which have high connection reliability and minute copper wiring layers, so that it has high connection reliability and is excellent in miniaturization of copper wiring layers. Therefore, according to the present invention, a multilayer wiring board having an interlayer connection which has high connection reliability and is optimum for miniaturization of the copper wiring layers and excellent in productivity is obtained.

The present invention provides a multilayer wiring board having an interlayer connection that has high connection reliability and is optimum for miniaturization of copper wiring layers and has excellent productivity, and a method for producing the same.

### Embodiment 3

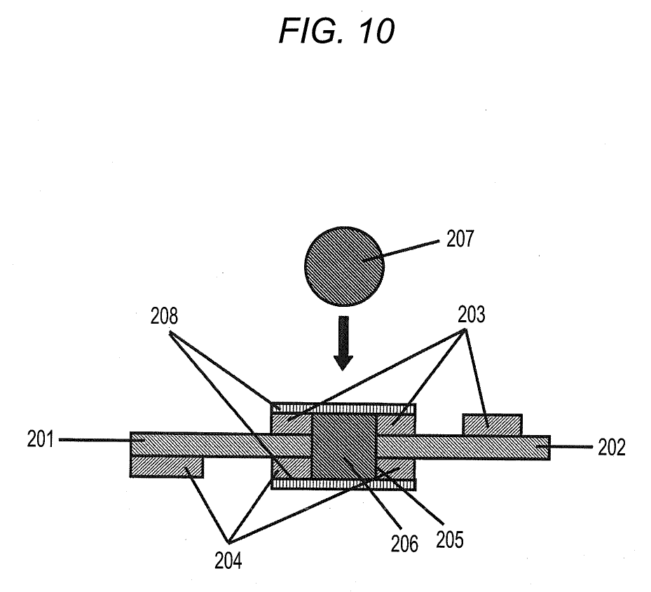

Hereinafter, a multilayer wiring board of a third embodiment of the present invention will be described. First, a multilayer wiring board of the present invention will be described with reference to FIG. 10. FIG. 10 is an essential portion sectional view of a multilayer wiring board in an embodiment of the present invention. In an embodiment of the present invention, a multilayer wiring board using an electric insulating film is mainly described, and a multilayer wiring board using a glass epoxy substrate is also basically similar, so that detailed description thereof is not given here.

In FIG. 10, the reference numeral 201 denotes a multilayer wiring board having a copper wiring upper layer 203 and a copper wiring lower layer 204 formed on both surfaces of an insulating layer 202 formed of a polyimide film, and interlayer connection between the copper wiring layers is made by a solder conductor 206 filled inside the through hole 205. Here, the solder conductor 206 is formed by press-fitting and filling one substantially spherical solder ball 207 in a deformed manner into the through hole 205 without gaps. Further, the surfaces of the filled solder conductor 206 and the surfaces of the copper wiring layers are coated and integrated by metallic films 208 made of copper nanoparticles.

As shown in FIG. 10, the solder conductor 206 which makes an interlayer connection of the multilayer wiring board 201 can be formed by press-fitting in a deformed manner the solder ball 207 so that the solder ball 207 comes into contact with the inside of the through hole 206 without gaps, and is joined to the copper wiring upper layer 203 and the copper wiring lower layer 204. Further, the surfaces of the solder conductor 206 and the surfaces of the copper wiring layers are coated and integrated by the metallic films 208 made of copper nanoparticles, and these copper plating films 208 restrict the solder conductor 206 which expands when heating, whereby a structure which suppresses thermal stresses is obtained.

Normally, by sintering and integrating metal nanoparticles by heating a conductive nanoink obtained by dispersing metal nanoparticles whose surfaces are coated by organic protective films in an organic solvent, the metallic films made of metal nanoparticles are formed. When the metal nanoparticles are a base metal, the particle surfaces are oxidized by heating for sintering and hinder sintering and make it difficult to form metallic films. In the case of joining to a base metal such as solder or copper, oxide films also hinder metal joining, so that metal joining cannot be obtained.

However, by containing an organic acid which develops an oxide film removal performance when heating in the organic solvent of the conductive nanoink, oxide films can be removed simultaneously by heating for sintering and integrating the metal nanoparticles, so that metallic films in which base metal nanoparticles are sintered and integrated can be formed and solder and copper surfaces can be firmly joined to each other by metal joining via the metallic films. Accordingly, the biggest problem in the case of using solder for an interlayer connection, in which solder inside the through hole expands more than the insulating layer when the conductor made of only the solder is heated, the joining interfaces between the copper wiring layers on the insulating layer surfaces and the solder separate, and thermal connection reliability cannot be secured, can be solved. Therefore, in the structure of the invention, high connection reliability is obtained.

As the solder conductor 206, a copper-core solder ball that has a copper piece smaller than the through hole 205 in its core, and whose surface is coated with a solder metal layer, may be filled. In this case, copper with excellent consistency in the thermal expansion coefficient with the insulating layer 202 is included in the core of the solder conductor 206, so that the thermal expansion coefficient of the entire solder conductor 206 can be optimized, and thermal stresses caused by a thermal expansion difference can be reduced, and higher connection reliability is obtained. Either of the solder conductors described above may be used as appropriate. As solder composition of the solder conductor 206, any of eutectic solder, high-temperature solder, lead-free solder, etc., may be used as appropriate.

As the insulating film 202, electric insulating films such as a polyimide film, a PET (polyethylene terephthalate) film, a PEN (polyethylene naphthalate) film, a polyester film, a polyamide-imide film, a PEI (polyether imide) film, a PEEK (polyether etherketon) film, a PES (polyether sulfone) film, a PPS (polyphenylene sulfide) film, an aramid film, an LCP film, a PTFE (polytetrafluoroethylene) film, etc., can be used, and any of these can be used as appropriate. Among these, a polyimide film that has excellent heat resistance, dimensional stability, and machinability is most preferably used. Further, when a glass epoxy base material is used as the insulating layer 202, as a thermosetting resin, a phenol resin, a melamine resin, a polyester resin, a diallyphthalate resin, and an epoxy resin, and a resin material containing modified resins of these resins can be used, and in this thermosetting resin, paper, fiber, glass fiber, and unwoven fabric (any of synthetic, natural, inorganic, and organic fibers) may be used, and any of these can be used as appropriate.

The metal nanoparticles contained in the conductive nanoink are a single metal selected from a group of metal elements of copper, silver, gold, nickel, platinum, palladium, and aluminum, or an alloy made of two or more metals selected from a group of metal elements of gold, silver, copper, platinum, palladium, nickel, and aluminum. Examples of these are gold-silver alloy, gold-copper alloy, gold-platinum alloy, gold-palladium alloy, silver-palladium alloy, silver-nickel alloy, copper-palladium alloy, copper-nickel alloy, and platinum-palladium alloy. As an organic solvent contained in the conductive nanoink, nonpolar solvents or low-polarity solvents which do not easily volatilize at a temperature around room temperature and have a comparatively high boiling point, for example, terpineol, mineral spirits, xylene, toluene, tetradecane, dodecane, etc., are preferably used.

As the organic protective films coating the surfaces of the metal nanoparticles, one or more compounds which have a group containing any of nitrogen, oxygen, and sulfur atom as a group which can be coordinate-bonded to the metal nanoparticles are coated. Such coating organic compounds are compounds having an amino group such as alkylamine, compounds having a sulfonyl group such as alkanethiol, or compounds having a hydroxy group such as alkane diol. Further, preferably, these organic compounds finally separate from the metal nanoparticle surfaces in the heating process and have a boiling point in a range enabling evaporation removal.

As an organic acid contained in the organic solvent of the conductive nanoink, a simple substance of abietic acid, or an organic acid such as lactic acid, citric acid, stearic acid, acetic acid, or formic acid, and basic organic compounds of these, or basic organic compounds such as aniline hydrochloride and hydrazine hydrochloride are used as an activator, and in the heating process for forming metallic films by sintering and integrating the metal nanoparticles, the organic acid is gasified into hot gas and can develop an oxide film removal performance.

Due to the oxide film removal performance of the organic acid, even when base metal nanoparticles such as copper nanoparticles are used, oxide films caused by heating can be removed, so that firm metallic films can be formed. Further, oxide films on the solder and the copper wiring layer surfaces can also be removed, so that the solder and the copper wiring layers are coated and integrated by metal joining via metallic films made of the metal nanoparticles, and joining with high reliability is possible.

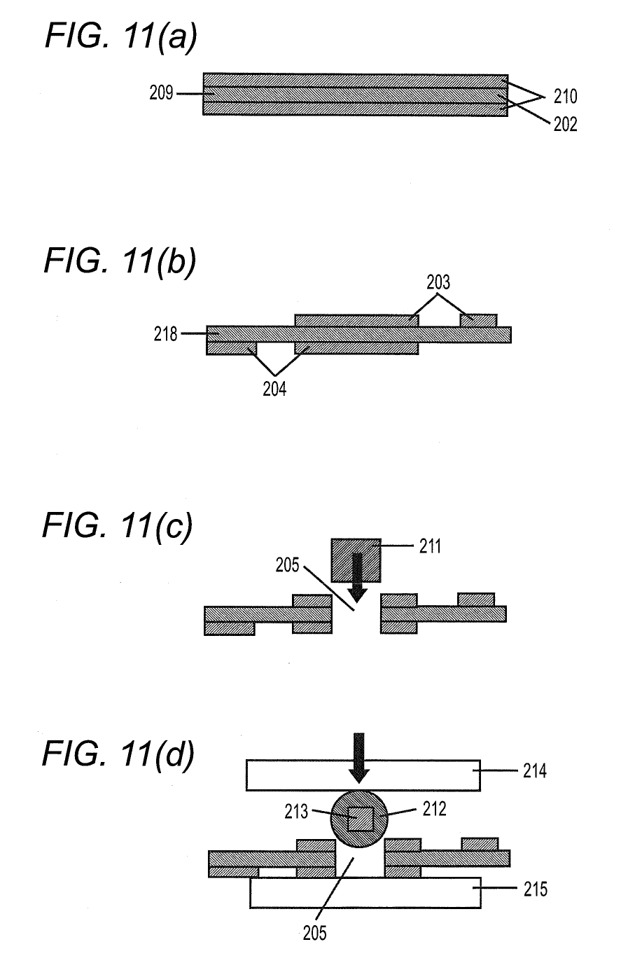

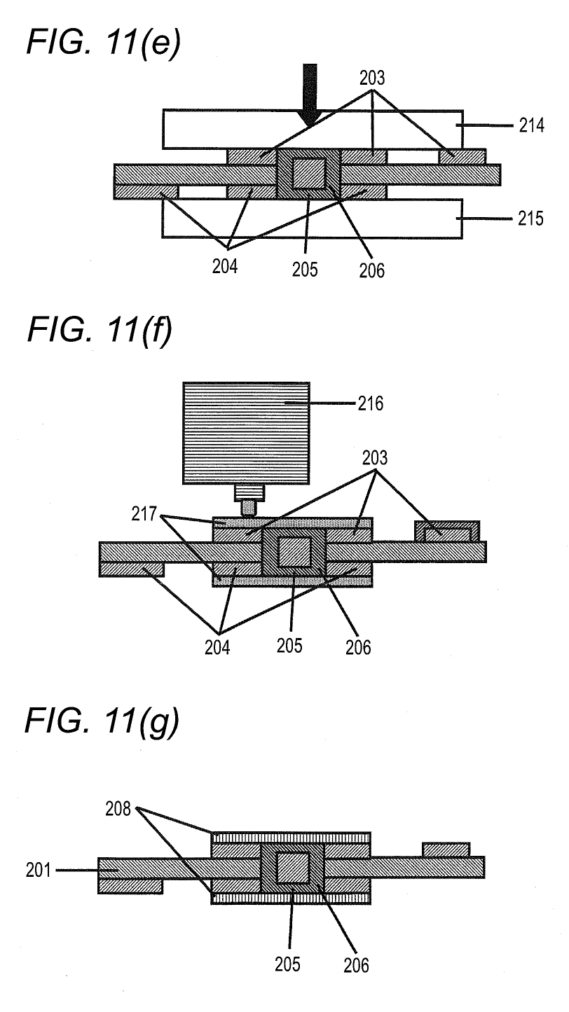

Next, a case where a copper-core solder ball is used in a method for producing such a multilayer wiring board with high connection reliability will be described in detail with reference to FIG. 11 to FIG. 13. The reference numerals that are the same as in FIG. 10 also basically indicate the same components in FIG. 11 to FIG. 13, so that description thereof is omitted here.

First, a method for producing a multilayer wiring board of an embodiment of the present invention will be described with reference to FIG. 11. FIG. 11 is a process chart of a multilayer wiring board in a third embodiment of the present invention. FIG. 11(a) is an essential portion sectional view of a double-sided copper-clad lamination board which is a raw material in an embodiment of the present invention, FIG. 11(b) is an essential portion sectional view of a double-sided wiring board on which copper wiring layers are formed, FIG. 11(c) is an essential portion sectional view of the double-sided wiring board in which a through hole is formed in an embodiment of the present invention, FIG. 11(d) is an essential portion sectional view of the double-sided copper-clad lamination board before a copper-core solder ball is press-fitted in an embodiment of the present invention, FIG. 11(e) is an essential portion sectional view of the double-sided copper-clad lamination board after the copper-core solder ball is press-fitted in a deformed manner in an embodiment of the present invention, FIG. 11(f) is an essential portion sectional view of the double-sided copper-clad lamination board during coating of a conductive nanoink made of copper nanoparticles in an embodiment of the present invention, and FIG. 11(g) is an essential portion sectional view of the multilayer wiring board in which copper wiring layers between which an interlayer connection is made are formed in an embodiment of the present invention.

In FIG. 11, the reference numeral 209 denotes a double-sided copper-clad lamination board having copper foils 210 directly formed on both surfaces of an insulating layer 202, and 211 denotes a punching die for machining a through hole. The reference numeral 212 denotes a substantially spherical copper-core solder ball having a copper piece 213 in its core. The reference numeral 214 and 215 denote a pressurizing upper plate and a pressurizing lower plate for press-fitting the copper-core solder ball 212 in a deformed manner. The reference numeral 216 denotes an ink-jet head for forming conductive nanoink 217 made of copper nanoparticles.

First, as shown in FIG. 11(a), the double-sided copper-clad lamination board 209 having copper foils 210 directly formed on both surfaces of the insulating layer 202 is prepared. In an embodiment of the present invention, a two-layer type having no bonding layer between the insulating layer 202 and the copper foils 210 is shown, however, a three-layer type including a bonding layer may also be used, and either of these can be used as appropriate, and the type is not limited to these.

Next, as shown in FIG. 11(b), a mask material is formed on the surfaces of the copper foils 210 and etching is performed by using a copper etchant such as iron chloride or copper chloride, whereby a double-sided wiring board 218 on which the copper wiring upper layer 203 and the copper wiring lower layer 204 are formed is obtained.

Next, as shown in FIG. 11(c), by punching by using a punching die 211 a through hole 205 is formed. In an embodiment of the present invention, punching is used, however, depending on the type of the insulating layer 202 and the size and accuracy of the through hole, drilling, laser machining, and etching can also be used, and any of these can be used as appropriate, and the method is not limited to these.

Further, as shown in FIG. 11(d), after the copper-core solder ball 212 having the copper piece 213 in its core is disposed at the position of the through hole 205, press-fitting in a deformed manner of the copper-core solder ball 212 into the through hole 205 is started by the pressurizing upper plate 214 and the pressurizing lower plate 215. As a method for disposing the copper-core solder ball 212, a conventionally known method in which solder balls are mounted on a semiconductor package called BGA can be diverted. In detail, an adsorption plate provided with a suction hole with a diameter smaller than the copper-core solder ball at a position corresponding to the through hole 205 is prepared, and is connected to a vacuum pump for adjustment of the pressure inside the suction hole. The copper-core solder ball is suctioned into the suction hole by using the suction plate, and positioned above the through hole 205, and the copper-core solder ball is dropped and disposed at the through hole position. Equipment called a ball mounter that performs these operations may be used. Here, an example of mounting of the copper-core solder ball 212 by means of vacuum adsorption is shown, however, other methods such as electrostatic adsorption can also be used.

Further, as shown in FIG. 11(e), the copper-core solder ball 212 is press-fitted in a deformed manner into the through hole 205 by the pressurizing upper plate 214 and the pressurizing lower plate 215, whereby a solder conductor 206 filled in the through hole 205 is formed. Here, the surface layer of the copper-core solder ball 212 is made of a soft metal of a solder alloy, so that it is successively deformed when it is press-fitted, and deformed along the inner wall of the through hole 205, and the inside of the through hole 205 can be completely filled with the solder conductor 206 without gaps. This filled solder conductor 206 makes electric continuity between the copper wiring upper layer 203 and the copper wiring lower layer 204. Herein, a production method in which a copper-core solder ball is filled in the through hole to form the solder conductor 206 is shown, however, a substantially spherical solder ball which does not include a copper core can also be filled. In this case, the solder ball is made of only solder of a soft material, so that it is easily filled in the through hole, and the operability can be improved and the tact time can be shortened, and further, production with high productivity without deforming the wiring layers is possible. Either of the solder balls may be used as appropriate, and the solder ball is not limited to these.

Further, as shown in FIG. 11(f), conductive nanoink 217 made of copper nanoparticles is coated to a uniform thickness of several hundreds of nanometers to several microns on solder exposed surfaces on which the solder conductor 206 is in contact with the copper wiring upper layer 203 and the copper wiring lower layer 204 and exposed to the outermost surfaces and the surfaces of the copper wiring upper layer 203 and the copper wiring lower layer 204 by using the ink-jet head. As a method for printing the conductive nanoink used herein, an ink-jet method or a screen printing method can be used. Either of these can be used as an appropriate method, and the method is not limited to these.

As a heating method, an electric furnace, a gas furnace, a halogen lamp heater, laser heating, etc., can be used. Any of these can be used as appropriate, and the method is not limited to these.

Last, as shown in FIG. 11(g), by heating the conductive nanoink, metallic films 108 in which copper nanoparticles are sintered and integrated are obtained. A multilayer wiring board 101 in which the surfaces on which the solder conductor 106 is exposed and the copper wiring layer surfaces are coated and integrated by metal joining via the metallic films 108 made of copper nanoparticles, is obtained. The metallic films 108 made of copper nanoparticles reliably suppress the solder conductor 106 that thermally expands at the interlayer connecting portion, so that high connection reliability can be obtained.

In the form of the production according to this production method, a plurality of products can be arranged on a hoop-like or sheet-like raw material and subjected to the respective processes, and the product external forms can be cut out in the final process. Particularly, roll to roll method is a production form with excellent productivity, and is most preferable.

The method for producing a multilayer wiring board in an embodiment of the present invention obtained as described above has the following features. First, the exposed surfaces of the solder conductor making an interlayer connection and the copper wiring layer surfaces are metal-joined and coated by metallic films made of copper nanoparticles to have an integral structure, so that stresses caused by a thermal expansion difference can be suppressed and high connection reliability is obtained. Further, on only the copper wiring layer surfaces in the vicinities of the exposed surfaces including the exposed surfaces of the solder conductor, the metallic films made of copper nanoparticles are formed thinly for an interlayer connection, so that the metallic films have no influence on the rest of the copper wiring layers, and this is suitable for miniaturization of the copper wiring layers. Last, interlayer connection can be made by very simple processes of filling of a copper-core solder ball and conductive nanoink coating, so that in comparison with other interlayer connection methods, the number of processes is smaller and the productivity is remarkably improved. Therefore, according to the present invention, a multilayer wiring board having an interlayer connection that has high connection reliability and is optimum for miniaturization of the copper wiring layers, and has excellent productivity, is obtained.

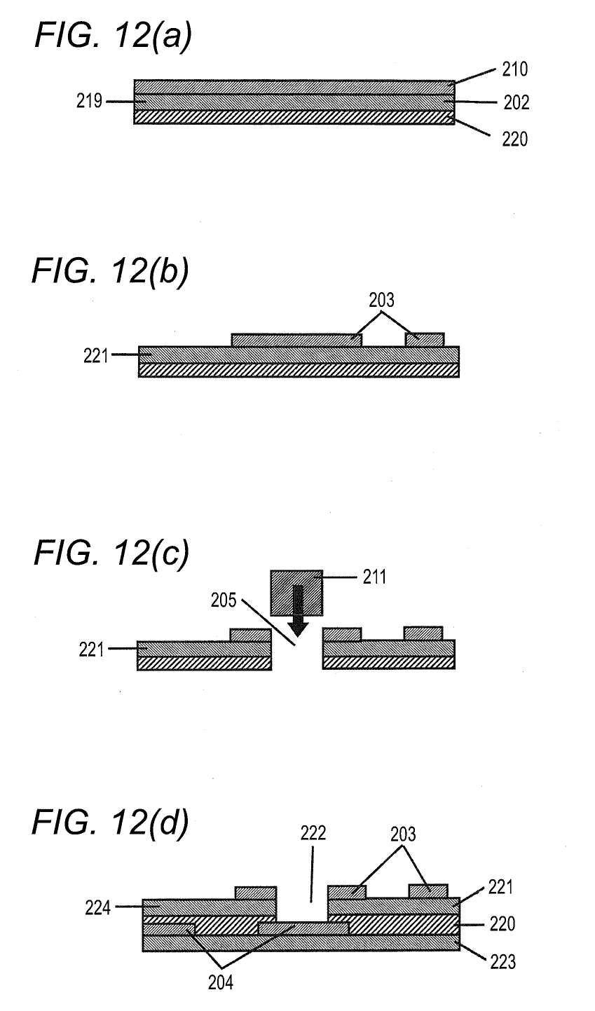

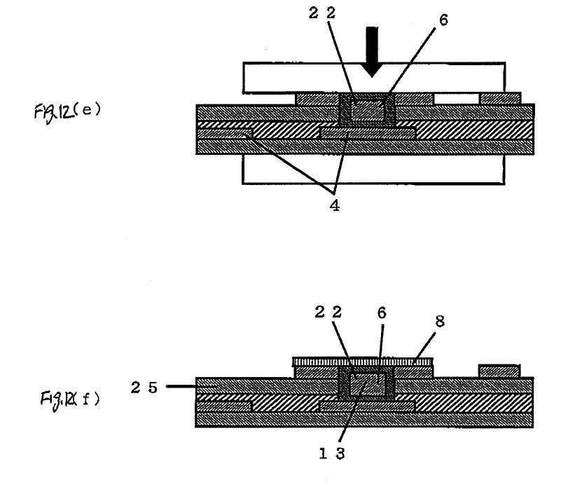

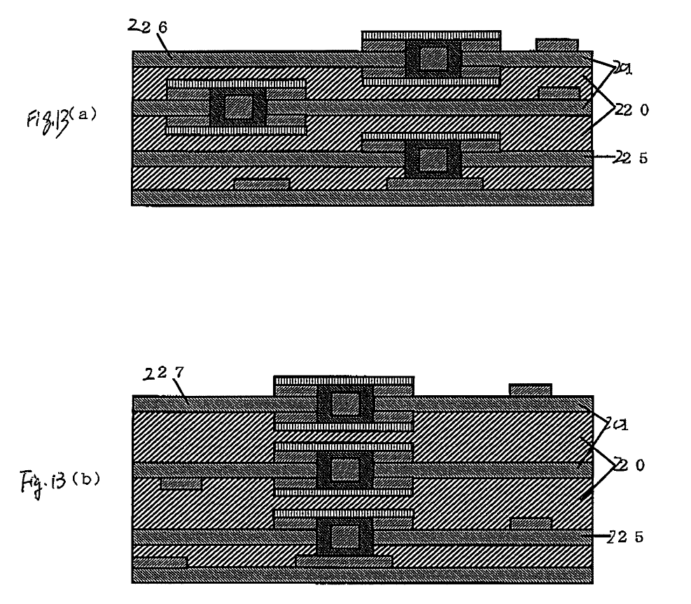

Next, a method for producing a multilayer wiring board in an embodiment of the invention which is more excellent in connection reliability and miniaturization of copper wiring layers will be described with reference to FIG. 12. FIG. 12(a) is an essential portion sectional view of a one-sided copper-clad lamination board with a bonding layer as a raw material in an embodiment of the present invention, FIG. 12(b) is an essential portion sectional view of a one-sided wiring board with a bonding layer on which a copper wiring layer is formed in an embodiment of the present invention, FIG. 12(c) is an essential portion sectional view of the one-sided wiring board with a bonding layer in which a through hole is formed in an embodiment of the present invention, FIG. 12(d) is an essential portion sectional view of a multilayer wiring board in which a blind via hole is formed in an embodiment of the present invention, FIG. 12(e) is an essential portion sectional view of a double-sided wiring board after a copper-core solder ball is press-fitted in a deformed manner in an embodiment of the present invention, and FIG. 12(f) is an essential portion sectional view of a multilayer wiring board after an interlayer connection is made by forming a metallic film made of copper nanoparticles in an embodiment of the present invention.

In FIG. 12, the reference numeral 219 denotes a one-sided copper-clad lamination board with a bonding layer that has a copper foil 210 formed on one surface and a bonding layer 220 formed on the other surface. The reference numeral 221 denotes a one-sided wiring board with a bonding layer obtained by forming a copper wiring upper layer 203 by etching the one-sided copper-clad lamination board 219 with a bonding layer. The reference numeral 223 denotes another one-sided wiring board to be laminated on the one-sided wiring board 221 with a bonding layer. The reference numeral 224 denotes a multilayer wiring board which has a blind via hole 222 for an interlayer connection formed by laminating the one-sided wiring board 221 with a bonding layer and the one-sided wiring board 223. The reference numeral 225 denotes a multilayer wiring board which has a solder conductor 206 filled in the blind via hole 222 and a metallic film 208 made of copper nanoparticles which coats and integrates the exposed surface of the solder conductor 6 and the surface of the copper wiring upper layer 203.

First, as shown in FIG. 12(a), the one-sided copper-clad lamination board 219 with a bonding layer which has the copper foil 210 directly formed on one surface of the insulating layer 202 and a bonding layer 220 formed on the other surface is prepared, and as shown in FIG. 12(b), the copper wiring upper layer 203 is formed by etching, whereby a one-sided wiring board 221 with a bonding layer is obtained. The copper wiring upper layer 203 of the one-sided wiring board 221 with a bonding layer obtained herein can be subjected to one-side etching suitable for miniaturization, so that it can be further miniaturized in comparison with the copper wiring layers of the double-sided wiring board described above.

The reason for this is described as follows. Normally, in formation of the copper wiring layers of the double-sided wiring board, to simultaneously etch copper foils on both surfaces of the double-sided copper-clad lamination board, an etchant must be applied uniformly from the upper and lower sides of the double-sided copper-clad lamination board. However, when an etchant is pressure-sprayed from the upper and lower sides of the double-sided copper-clad lamination board, the etchant sprayed on the upper surface forms an etchant pool on the upper surface and the etchant cannot be maintained uniform. Therefore, on the double-sided wiring board, etching conditions become unstable and it is difficult to form very minute copper wiring layers. On the other hand, in formation of the copper wiring layer of the one-sided wiring board, the etchant is sprayed from the lower side, so that a pool of the etchant is not formed, and optimum ranges of etching conditions become wide, and this is suitable for miniaturization of the copper wiring layer.

Next, as shown in FIG. 12(c), the one-sided wiring board 221 with a bonding layer is subjected to punching by using a punching die 212 to form a through hole 205, and as shown in FIG. 12(d), the one-sided wiring board 221 with a bonding layer and another one-sided wiring board 223 on which a copper wiring lower layer 204 is formed are bonded via the bonding layer 220, whereby a multilayer wiring board 224 in which a blind via hole 222 for an interlayer connection is formed is obtained. The multilayer wiring board 224 obtained herein is formed by laminating one-sided wiring boards having minurte copper wiring layers, so that in comparison with the wiring layers of the double-sided wiring boards, the copper wiring layers become more minute. As a method for laminating the one-sided wiring boards in an embodiment of the present invention, the multilayer wiring board 224 is shown, however, even when a double-sided wiring board is formed by bonding two one-sided wiring boards together via a bonding layer so that their copper wiring layers become the outermost layers, the copper wiring layers can be miniaturized. Either of the lamination methods can be used as an appropriate method, and the method is not limited to these.

Further, as shown in FIG. 12(e), a copper-core solder ball is press-fitted in a deformed manner into the blind via hole 222 to form a solder conductor 206. The solder conductor 206 obtained herein is filled in the blind via hole 222 which has the copper wiring lower layer 204 on its bottom surface, so that in comparison with the through hole, the joining area between the solder conductor 206 and the copper wiring lower layer 204 increases, and the adhesion strength between these also increases. Therefore, even when various external stresses are applied, the joint interface between the copper wiring lower layer 204 and the solder conductor 6 does not separate, and higher connection reliability is obtained.

Last, as shown in FIG. 12(f), by coating and heating conductive nanoink made of copper nanoparticles, a multilayer wiring board 225 in which a metallic film 208 made of copper nanoparticles coats and integrates the exposed surface of the solder conductor 6 and the surface of the copper wiring upper layer 203 and metal-joins these, is obtained.

According to the method for producing a multilayer wiring board in an embodiment of the present invention obtained as described above, one-sided wiring boards are laminated, so that in comparison with copper wiring layers of a double-sided wiring board, the copper wiring layers become more minute. Further, a solder conductor is filled in the blind via hole by press-fitting a copper-core solder ball in a deformed manner, so that in comparison with the through hole, higher connection reliability is obtained. Therefore, according to the present invention, a multilayer wiring board having an interlayer connection which has high connection reliability and is optimum for miniaturization of the copper wiring layers, and has excellent productivity is obtained.

Finally, a multilayer wiring board of an embodiment of the present invention in which more multilayer wiring boards described above are laminated will be described with reference to FIG. 13. FIG. 13(a) is an essential portion sectional view of a multilayer wiring board after being laminated in an embodiment of the present invention, and FIG. 13(b) is an essential portion sectional view of another multilayer wiring board after being laminated in an embodiment of the present invention.

In FIG. 13, the reference numeral 226 denotes a multilayer wiring board formed by laminating a multilayer wiring board 201 and a multilayer wiring board 225 via a bonding layer 220. First, as shown in FIG. 13(a), the multilayer wiring board 201 and the multilayer wiring board 225 produced according to a third embodiment of the present invention described above are further laminated via the bonding layer 220, whereby a multilayer wiring board 226 including an increased number of copper wiring layers is obtained. In the multilayer wiring board 226 obtained herein, the multilayer wiring board 201 and the multilayer wiring board 225 which are components have high connection reliability and minute copper wiring layers, so that the multilayer wiring board has high connection reliability and is excellent in miniaturization of copper wiring layers.

As shown in FIG. 13(b), the above-described multilayer wiring board 201 and the multilayer wiring board 225 are laminated so that the metallic films 208 made of copper nanoparticles of the boards come into contact with each other, whereby the multilayer wiring board 227 is obtained. Herein, the metallic films 208 made of copper nanoparticles are homogenous metal layers, so that electric continuity of the wiring layers can be made.

The multilayer wiring board in an embodiment of the present invention obtained as described above is formed by further laminating multilayer wiring boards which have high connection reliability and minute copper wiring layers, so that it has high connection reliability and is excellent in miniaturization of copper wiring layers. Therefore, according to the present invention, a multilayer wiring board having an interlayer connection which has high connection reliability and is optimum for miniaturization of the copper wiring layers and excellent in productivity is obtained.

This application based upon and claims the benefit of priority of Japanese Patent Application No 2007-319174 filed on 7/12/11 and Japanese Patent Application No 2007-319175 filed on 07/12/11, the contents of which are incorporated herein by reference in its entirety.

What is claimed is:

1. A multilayer wiring board, comprising:
an insulating layer;
copper wiring layers laminated on both surfaces of the insulating layer;
a through hole pierced through the insulating layer and at least one of the copper wiring layers; and
a solder conductor filled in the through hole and makes connection and electric continuity between the copper wiring layers;
wherein solder exposed surfaces on which a part of the solder conductor is in contact with the copper wiring layers and exposed to the outermost surfaces and the surfaces of the copper wiring layers are coated by metal plating films, the solder conductor and the wiring layers are joined by the metal plating films, and the metal plating films are made of a metal whose ionization tendency is greater than that of the solder conductor.

2. The multilayer wiring board according to claim 1, wherein the solder conductor has a copper piece smaller than the through hole diameter in its core, and the surface of the solder conductor is coated by a solder metal layer.

3. The multilayer wiring board according to claim 1, wherein the metal plating films contain at least one of nickel and a nickel alloy.

4. The multilayer wiring board according to claim 1, wherein at least one kind of different metal is laminated on the surfaces of the metal plating films.

5. The multilayer wiring board according to claim 1, wherein the metal plating films are partially plated on only regions including ranges filled with the solder conductor.

6. A method for producing a multilayer wiring board comprising:
forming a solder conductor by forming a through hole pierced through copper wiring layers and an insulating layer at a predetermined interlayer connecting position of a double-sided wiring board having the copper wiring layers formed on both surfaces of the insulating layer and then press-fitting and filling one substantially spherical solder ball into the through hole; and
making electric continuity between the copper wiring layers by electrodepositing nickel plating films by electrolytic nickel plating on solder exposed surfaces on which a part of the solder conductor is in contact with the copper wiring layers and exposed to the outermost surfaces and the surfaces of the copper wiring layers.

7. The method for producing a multilayer wiring board according to claim 6, wherein the double-sided wiring board is formed by bonding via a bonding layer two one-sided wiring boards each of which has a copper wiring layer formed on one surface of an insulating layer, in an orientation in which the copper wiring layers become the outermost layers.

8. The method for producing a multilayer wiring board according to claim 6, wherein the solder ball has a copper piece smaller than the through hole diameter in its core, and the surface of the solder ball is coated by a solder metal layer.

9. A method for producing a multilayer wiring board comprising:
forming a solder conductor by forming a through hole pierced through metal layers and an insulating layer at a predetermined interlayer connecting position of a double-sided metal lamination board having the metal layers formed on both surfaces of the insulating layer and then press-fitting and filling one substantially spherical solder ball into the through hole; and
obtaining metal layers interlayer-connected by electrodepositing plating films by alkaline electrolytic plating on solder exposed surfaces on which a part of the solder conductor is in contact with the metal layers and exposed to the outermost surfaces and the metal layers and then pattern-etching the metal layers coated by the plating films into a predetermined shape.

10. The method for producing a multilayer wiring board according to claim 9, wherein the double-sided wiring board is formed by bonding via a bonding layer two one-sided wiring boards each of which has a metal layer formed on one surface of an insulating layer, in an orientation in which the metal layers become the outermost layers.

11. The method for producing a multilayer wiring board according to claim 9, wherein the solder ball has a copper piece smaller than the through hole diameter in its core, and the surface of the solder ball is coated by a solder metal layer.

12. The method for producing a multilayer wiring board according to claim 9, wherein the metal layer and the plating films are made of copper.
